(19) United States
(12) Patent Application Publication
(10) Pub. No.: US 2008/0315326 A1
(43) Pub. Date: Dec. 25, 2008

(54) Method for forming an integrated circuit having an active semiconductor device and integrated circuit

(76) Inventors: Werner Graf, Dresden (DE); Ines Uhlig, Dresden (DE); Daniel Koehler, Chemnitz (DE); Joerg Radecker, Dresden (DE); Lars Heineck, Dresden (DE)

Correspondence Address: FAY KAPLUN & MARCIN, LLP, 150 BROADWAY, SUITE 702, NEW YORK, NY, 10038, US

(21) Appl. No.: 11/821,274

(22) Filed: Jun. 21, 2007

(51) Int. Cl. H01L 27/088; H01L 21/8239

(52) U.S. Cl. 257/401; 438/129; 257/E21.645; 257/E27.06

(57) ABSTRACT

An integrated circuit having an active semiconductor device is formed comprising a trench defined by conductor lines previously formed.

### BACKGROUND OF THE INVENTION

### Field of the Invention

The present invention relates to a method for forming an integrated circuit having an active semiconductor device, in particular a semiconductor memory device and a selection transistor. The present invention further relates to the formed integrated circuit.

### BRIEF SUMMARY OF THE INVENTION

According to a first aspect of the invention a method for forming an active device of a semiconductor device, comprising the steps of: providing a substrate comprising a substrate surface; forming conductor lines above the substrate surface and orientated along a first direction; forming a mask above the conductor lines; etching at least one trench into the substrate using the conductor lines as a masking structure and by using the mask to define the lateral dimension of the at least one trench along the first direction; and forming an active device in the at least one trench.

According to a second aspect of the invention a method for forming an integrated circuit having an active semiconductor device, comprising the steps of: providing a substrate comprising a substrate surface divided in support areas and memory field areas; forming a stack of a conductive lower layer and a protective cap layer in the support areas and memory field areas on the substrate surface; structuring the stack to conductor lines in the memory field area and to gate stack in the support area by a single lithographic mask; forming a mask above the conductor lines; etching at least one trench into the substrate using the conductor lines as a masking structure and by using the mask to define the lateral dimension of the at least one trench along the first direction; and forming an active device in the at least one trench.

According to a third aspect of the invention a method for forming a semiconductor comprises the steps of: providing a substrate having a substrate surface; structuring conductor lines on top of the substrate surface; and forming gate electrodes between the structured conductor lines extending down into the substrate.

According to a forth aspect a memory device comprises a plurality of conductor lines arranged on a substrate and a plurality of memory cells are arranged in the substrate, each memory cell is covered by two of the conductor lines and comprises an active device arranged in the middle below the two of the conductor lines.

### DESCRIPTION OF THE DRAWINGS

In the Figures:

FIGS. 1 to 33 are illustrating steps of a first embodiment forming an integrated circuit having an active semiconductor device;

FIGS. 34 to 41 are illustrating steps of a second embodiment forming an integrated circuit having an active semiconductor device;

FIGS. 42 to 67 are illustrating steps of a third embodiment forming an integrated circuit having an active semiconductor device;

FIGS. 68 to 77 are illustrating steps of a forth embodiment forming an integrated circuit having an active semiconductor device;

FIGS. 78 to 107 are illustrating steps of a fifth embodiment forming an integrated circuit having an active semiconductor device;

FIGS. 108 to 121 are illustrating steps of a sixth embodiment forming an integrated circuit having an active semiconductor device; and

FIG. 122 shows a further embodiment.

### DETAILED DESCRIPTION OF THE INVENTION

It is to be understood and appreciated that the process steps and structures described below do not form a complete process flow for the manufacture of integrated circuits. The present invention can be practiced in conjunction with integrated circuit fabrication techniques that are currently used in the art, and only so much of the commonly practiced process steps are included herein as are necessary to provide an understanding of the present invention. The drawing figures that are included with this specification and which represent cross-sections of portions of an integrated circuit during fabrication are not drawn to scale, but instead are drawn so as to illustrate the relevant features of the invention. In the Figures, like numerals refer to the same or similar functionality throughout the several views.

### First Embodiment

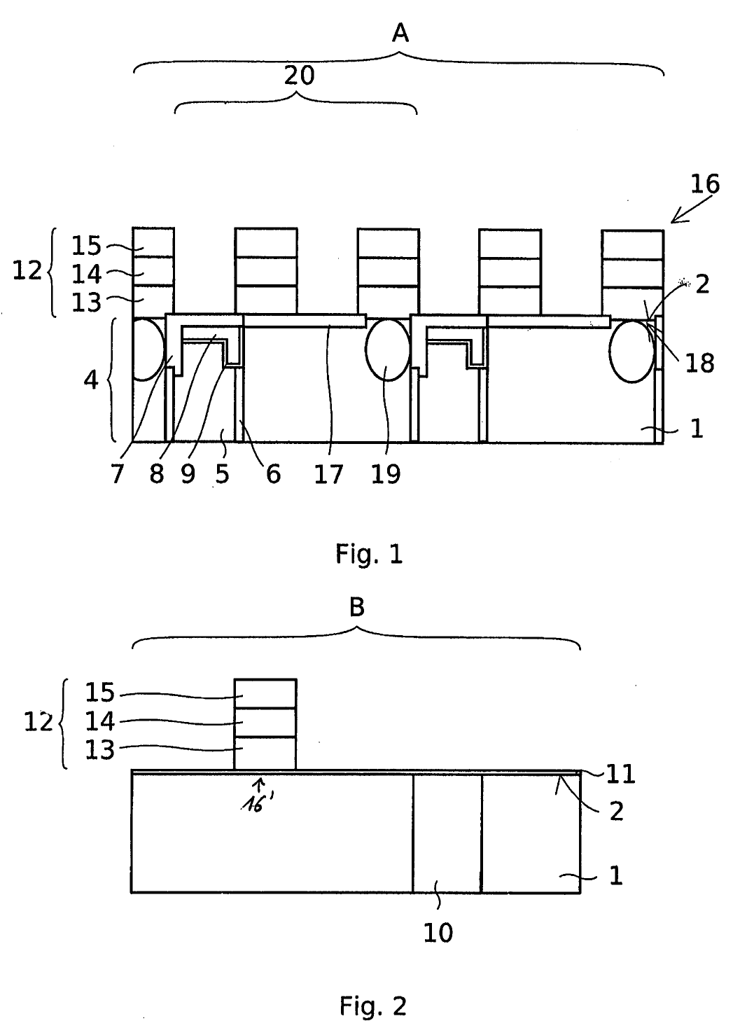

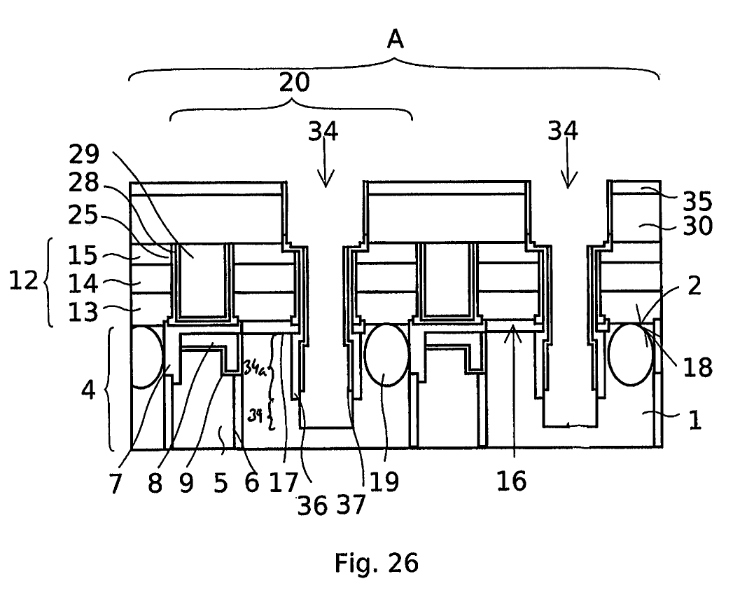

A first embodiment is given as an example of the invention, even though the invention is not limited thereon. Along with FIGS. 1 to 33 a formation of active devices, for instance selection transistors, and support transistors of a semiconductor memory device will be explained in detail.

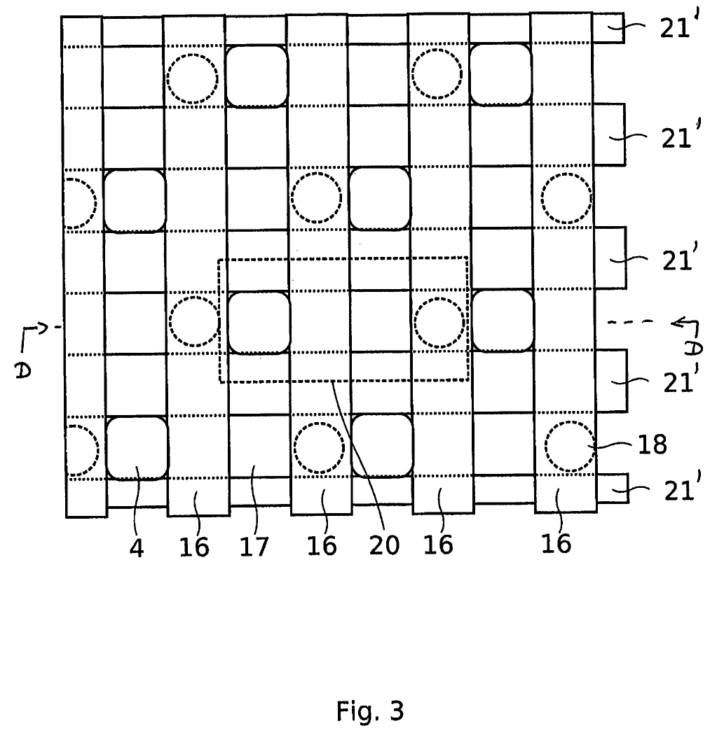

FIGS. 1 and 2 are showing partial cross-sections of a semiconductor substrate 1. The substrate surface 2 is divided in memory field areas A and support areas B, which are shown in FIG. 1 and FIG. 2, respectively. The lateral extension of a memory cell 20 is indicated in FIG. 1 and in a top view in FIG. 3. The lateral dimensions of the support area B and the memory field area A are not to scale with respect to each other.

The semiconductor substrate 1 may be of silicon, for instance provided as a silicon wafer. Other suitable semiconductor materials like silicon-germanium, germanium, gallium arsenide, etc can be used instead.

Each memory cell 20 comprises a capacitor structure. The capacitor structure 4 can be formed into the semiconductor substrate 1. The collar section of the capacitor structure 4 is illustrated in a cross-section in FIG. 1. The collar section comprises an inner electrode 5, an isolating layer 6, an isolating cap layer 7, a buried strap 8, and a conductive barrier layer 9. The buried strap 8 provides an electrical connection between the inner electrode 5 and a section of the substrate 1 of the respective memory cell 20. In a bottle region of the capacitor (not shown) the inner electrode 5 is surrounded by a capacitor dielectric. A common outer electrode of the capacitor structures may be formed in the substrate 1. The common outer electrode can be isolated from the memory cells 20 by a buried layer in the substrate 1.

An isolating layer 17 is deposited or formed on the substrate surface 2. A single opening 18 is provided into the isolating layer 17 for each memory cell 20. The arrangement of the openings 18 is exemplary illustrated in FIG. 3. The isolating layer 17 may be of silicon nitride and/or silicon oxynitride. A highly doped area 19 may be provided in the substrate 1 below the opening 18.

In the support area B, additional capacitors 10 or other passive elements may be formed. A gate dielectric 11 is provided selectively in the support area B, for instance by depositing the gate dielectric 11 and structuring the gate dielectric 11 by means of a mask.

Over the whole wafer or substrate 1, a stack 12 of a conductive layer and a protective layer is deposited. The conductive layer may be of two parts—a lower conductive poly-silicon layer 13 and an upper metallic layer 14. The poly-silicon layer 13 may be highly doped. The upper metallic layer 14 may be formed of tungsten, copper, aluminium, or any other suitable metallic material. Between the lower conductive poly-silicon layer 13 and the upper metallic layer 14 a thin barrier layer, for instance of tungsten nitride, may be provided. The protective layer 15 is deposited on the upper metallic layer 14. The protective layer 15 may made of or comprise at least one of silicon nitride and silicon oxynitride. The thickness of the protective layer 15 may be in the range of a 100 nm to 150 nm, at least of 50 nm, at least of 80 nm for instance.

The stack 12 is structured simultaneously in the memory field area A and the support area B by means of a single lithographic mask. In the memory field area A, conductor lines 16, for instance bit-lines are defined by the structured stack 12. The conductor lines 16 are running essentially in parallel and perpendicular to the isolation trenches 21′.

An exemplary arrangement of the conductor lines 16 is illustrated by the top view in FIG. 3. Above each memory cell 20 two conductor lines 16 are arranged. Each memory cell 20 is isolated from one of the two conductor lines 16 by the isolating layer 17 and connected to the other one of the two conductor lines 16 via the opening 18. Thus, each memory cell 20 is electrically connected to exactly one conductor line 16. In the support area B, the structured stack 12 forms gate stacks 16′ of transistors.

Isolation trenches 21 maybe arranged essentially perpendicular to the conductor lines the isolation trenches 21 are filled with a dielectric material, for instance with silicon oxide. 16. In the top view of FIG. 3 the isolation trenches 21 are partially covered by the conductor lines 16. The covered parts are indicated as dashed lines. The isolation trenches 21 and the capacitors structures are hence isolating each memory cell 20 from neighbouring memory cells 20.

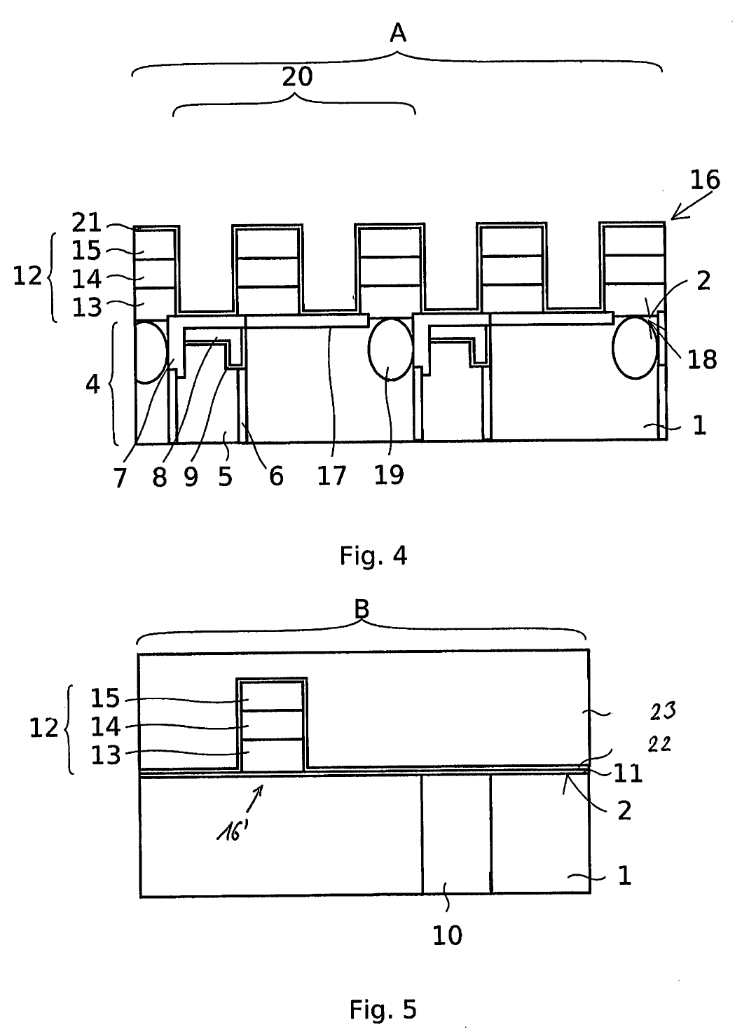

A liner layer 22 is deposited or grown on the whole wafer or substrate 1, i.e. in the memory field area A and the support area B (FIGS. 4 and 5). The liner layer 22 may be of silicon oxide. An oxide liner layer 22 can be deposited by a low pressure chemical vapour deposition technique (LPCVD). The thickness of the liner layer 22 is in the range of 2 nm to 8 nm, for instance at least 3 nm, at least 4 nm, at the most 6 nm, at the most 5 nm, about 4 nm.

The support area B is covered by a mask 23. The mask 23 may be formed of a lithographically structured resist. The liner layer 22 is removed in the memory field area A. A wet etch technology can be used, for instance a wet oxide solution based on hydrofluoric acid for removing an oxide liner layer 22.

The substrate 1 can be doped by an implantation step. A dopant material 24 can be implanted into the substrate 1 by means of a directed implantation towards the buried strap 8. A direction of the directed implantation may be inclined towards the substrate surface 2 at an angle of 70° to 90°, for instance 75° to 85°, about 80°.

The mask 23 is stripped from the support area B.

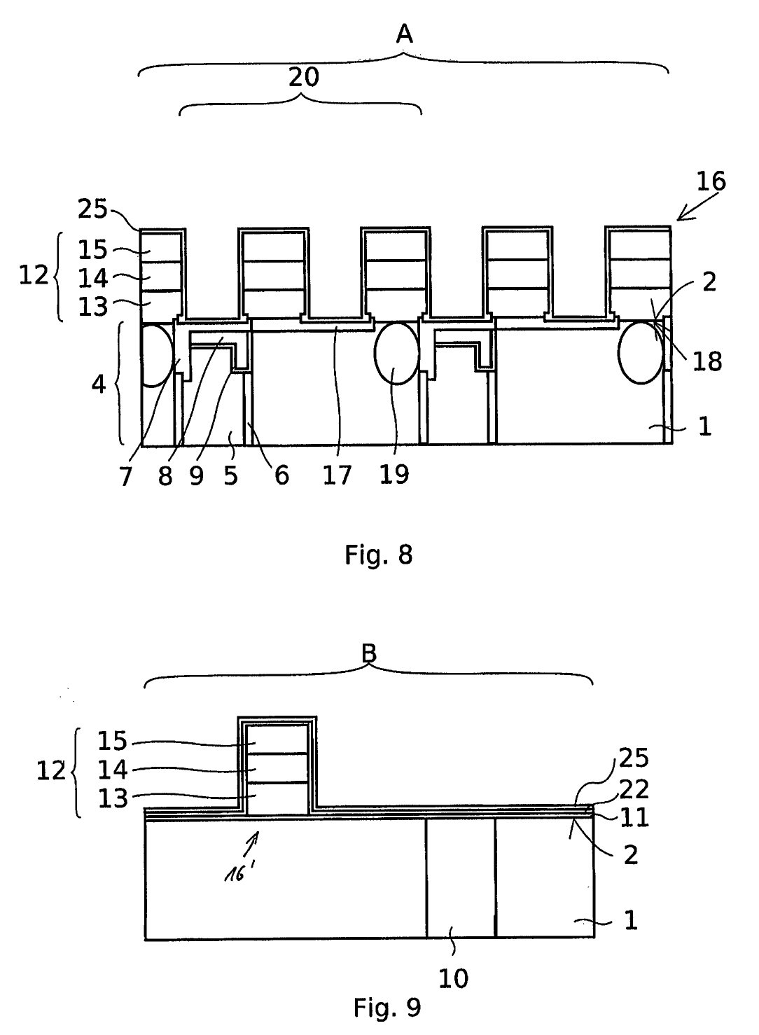

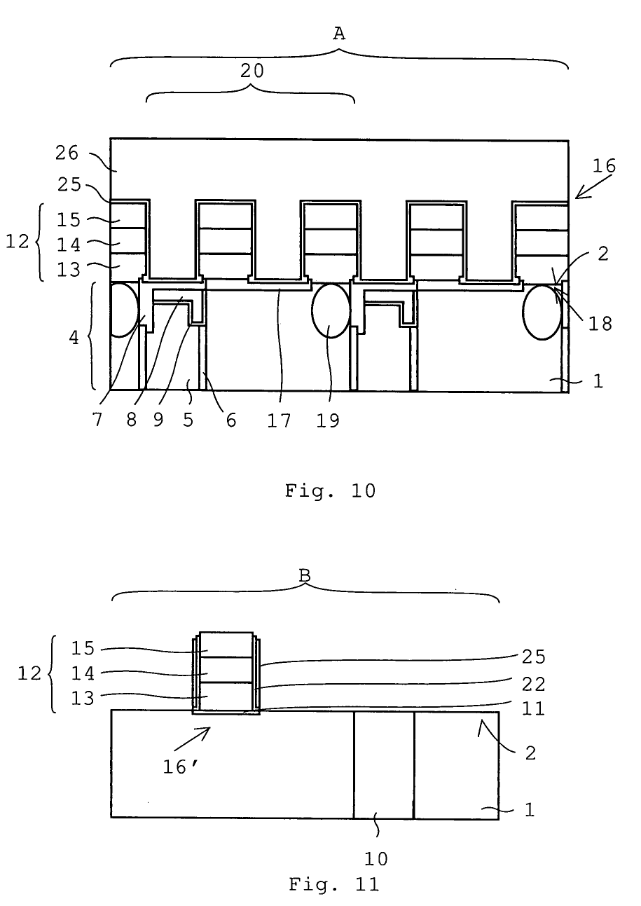

A covering layer 25 is deposited in the memory field area A and the support area B (FIGS. 8 and 9). The covering layer 25, to which may be referred to as spacer as well, may be formed of silicon nitride or silicon oxynitride. The covering layer 25 has a thickness which is significantly smaller than the distance between two neighbouring conductor lines 16, for instance less than a third of the distance between two neighbouring conductor lines 16. The thickness of the covering layer 25 may be in the range of about 2 nm to 8 nm, for instance about 4 nm to 7 nm, about 6 nm.

The memory field area A is covered by a mask 26. An anisotropic etching process is used to remove the covering layer 25, the liner layer 22, and the dielectric layer 11 from the surface 2 of the substrate 1 in the support area B (FIGS. 10 and 11). The side walls of the gate stack 16′ remain covered by the liner layer 22 and the covering layer 25. The anisotropic etching process reduces the thickness of the cap layer 15. The cap layer 15 has a minimal thickness of about 50 nm, for instance about 75 nm, about 90 nm. The mask 26 is removed from the memory field area A.

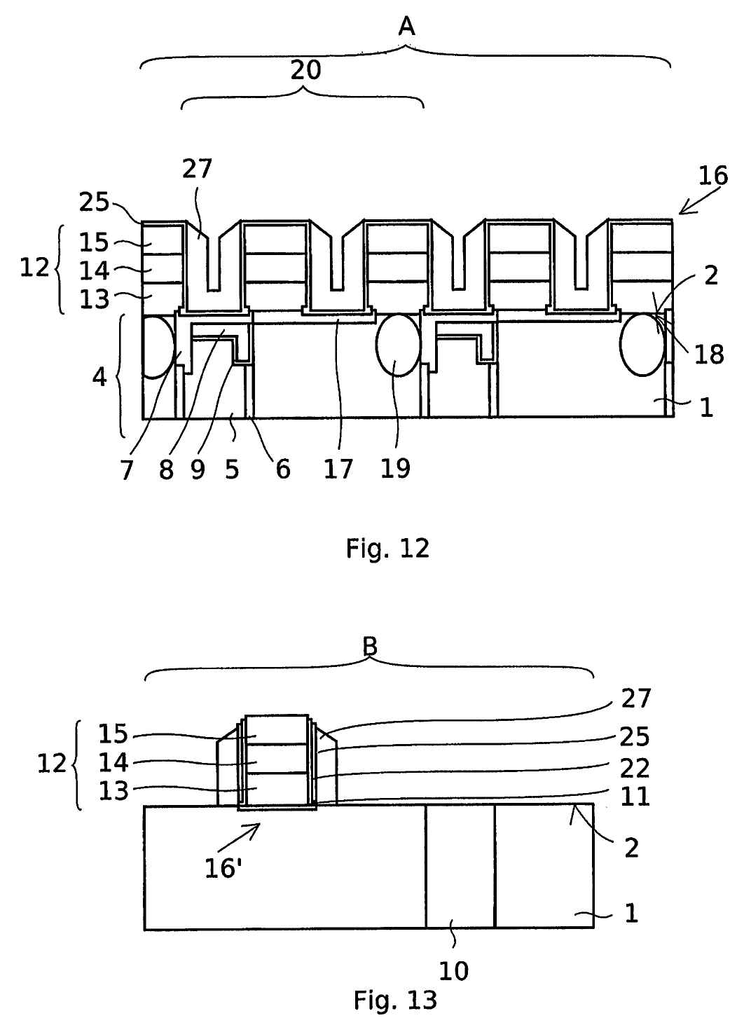

A spacer layer 27 is deposited in the memory field area A and the support area B (FIGS. 12 and 13). The thickness of the spacer layer 27 is for example 20% to 40% of the distance between neighbouring conductor lines 16. Hence, the spacer layer 27 may not completely fill the gap between neighbouring conductor lines 16. An exemplary thickness may be in the range of about 10 nm to 40 nm, about 20 nm to 35 nm, about 30 nm. The spacer layer 27 may comprise silicon oxide. The silicon oxide spacer layer 27 can be deposited by a low pressure TEOS process using tetra-(ethyl ortho) silica (TEOS). Other suitable deposition techniques can be employed, too. The spacer layer 27 is anisotropically etched such that vertical dimension of the spacer layer 27 is nominally reduced by a thickness larger than the thickness of the spacer layer 27 previously deposited. Thus, the spacer layer 27 just remains along the side walls of the gate stack 16′ and the side walls of the conductor lines 16.

Implantation steps of dopant materials can be proceeded to form the source and drain areas of the transistor in the support area B. The spacer liner 27 can be used as a self aligning mask for the implantation steps. Additional lithographic masks may be used for the implantation steps to define the p-channel and n-channel transistors. Annealing steps can be applied to the formed structure, for instance in order to activate the dopant materials.

An isotropic etching process can be applied to reduce the lateral thickness of the remaining spacer layer 27 to less than about 20 nm, less than about 15 nm, less than about 10 mm, about 10 nm, to at least 5 nm. Basically, the thickness of the spacer layer 27 along the side walls of the gate stack 16′ will be reduced. FIGS. 12 and 13 are exemplary illustrating the structured device manufactured by the above steps (the implanted dopant materials are not illustrated).

A block mask (not shown) covers the support area B. The spacer layer 27 is subsequently fully removed from the memory field area A by an etch step. A fluorine containing gas/plasma can be used in an isotropic reactive ion etching process in order to etch away a spacer layer 27 made of silicon oxide, for instance. A fluorine containing gas sufficiently selectively etches silicon oxide with respect to the covering layer 25 which may be made silicon nitride and the block mask made of resist in the support area B. Other etch reactants providing a similar selectivity can be employed additionally or instead. Afterwards, the block mask is stripped off.

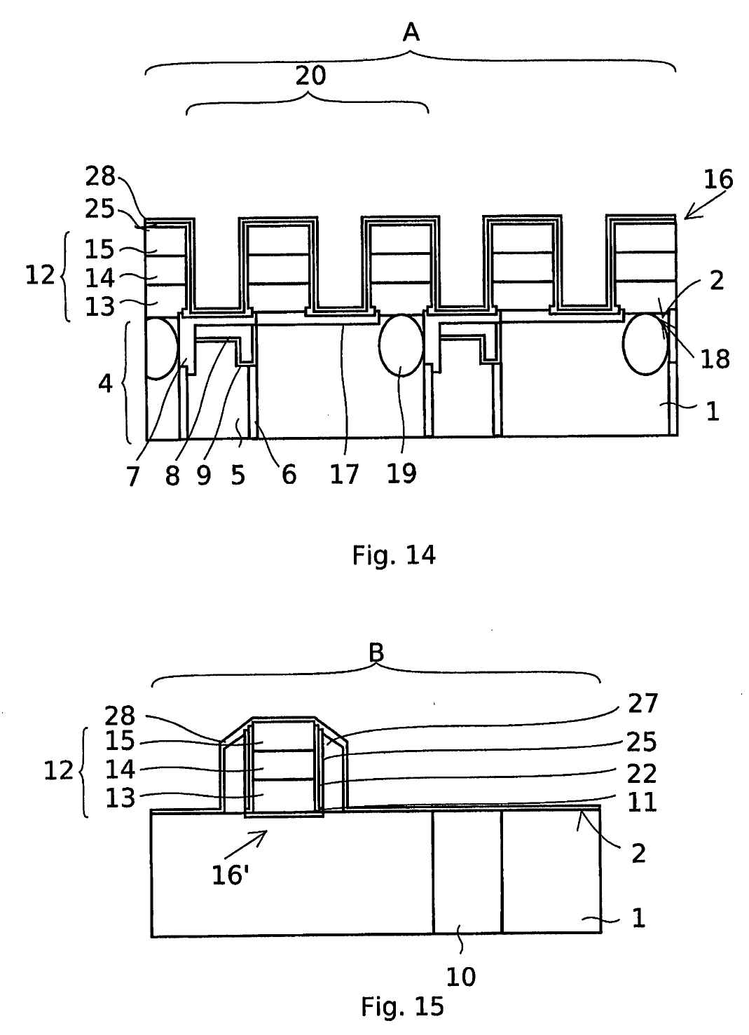

A second covering layer 28 is deposited in the memory field area A and the support area B (FIGS. 14 and 15). The second covering layer 28 may be deposited such that a mechanical stress is applied to the underlying layers, in particular to the gate stack 16′ and a gate channel area below the gate stack 16′. The thinned spacer layer 27, the thin (first) covering layer 25, and the thin liner layer 22 essentially transmit the stress without damping of the stress.

On one first-hand, the thickness of the second covering layer 28 is chosen such that the overall thickness of the first covering layer 25 and the second covering layer 28 remains significantly smaller than the distance between neighbouring conductor lines 16. On the other hand, the overall thickness should be at least about 8 nm, for instance at least about 10 nm, about 12 nm. Thus, the two parted covering layer 25, 28 will provide sufficient protection for the gate stack 16′ and the conductor lines 16 in the subsequent etching steps. For example, the thickness of the second covering layer 28 may be in the range of about 2 nm to 8 nm, about 4 nm to 7 nm, about 6 nm.

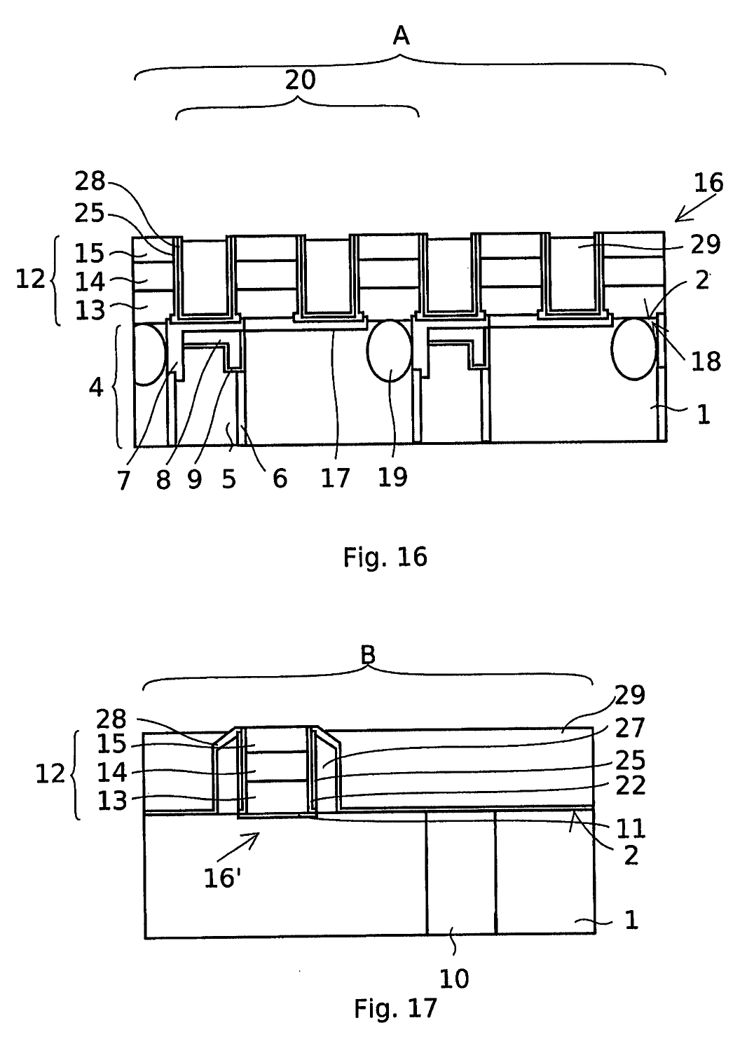

A silica glass 29, for instance a spin on glass (SOG), a boron phosphate glass (BPSG), a phosphate glass (PSG), is deposited in the memory field area A and the support area B. The silica glass can be doped. A high-temperature annealing step is applied in order to remove voids and to densify the silica glass 29. Thus, a silica glass layer 29 deposited on the gate stacks 16′ and the conductor lines 16 are removed by a chemical mechanical polishing step (FIGS. 16 and 17). Polish media achieving a higher polishing rate for silica glass 29 compared to the material of the second covering layer 28, for instance the silicon nitride, may be used for the chemical mechanical polishing step. Instead of a silica glass another spin-on-dielectric can be used.

The gaps between the conductor lines 16 basically remain filled with the silica glass 29. A top part of the two covering layers 25, 28 may be lost due to the chemical mechanical polishing step.

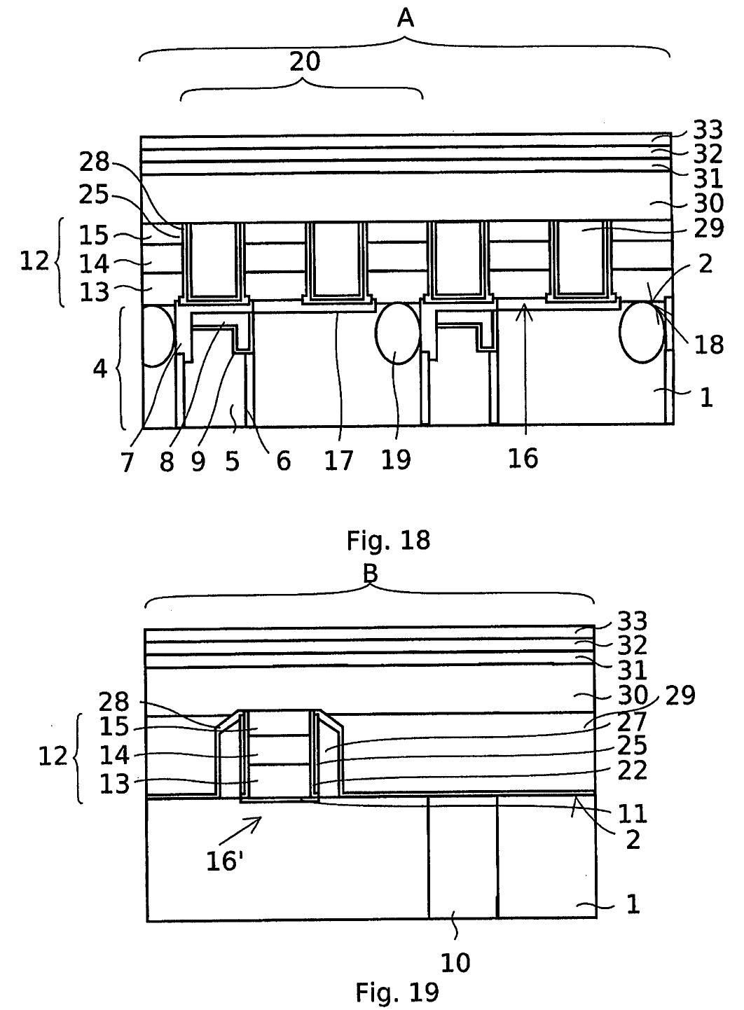

A doped silica glass 30, a silicon nitride layer 31, and an optional carbon-silicon layer 32, and an optional layer of silicon oxynitride 33 are deposited on the memory field area A and the support area B (FIGS. 18 and 19). The doped silica glass 30 may be provided to getter impurities during the manufacturing process of the semiconductor memory device, in particular potassium and sodium impurities are trapped in the doped silica glass 30.

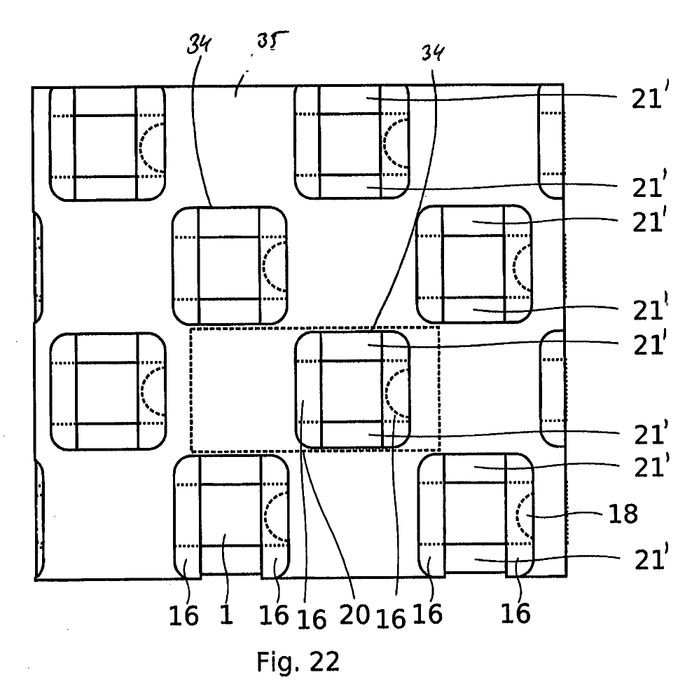

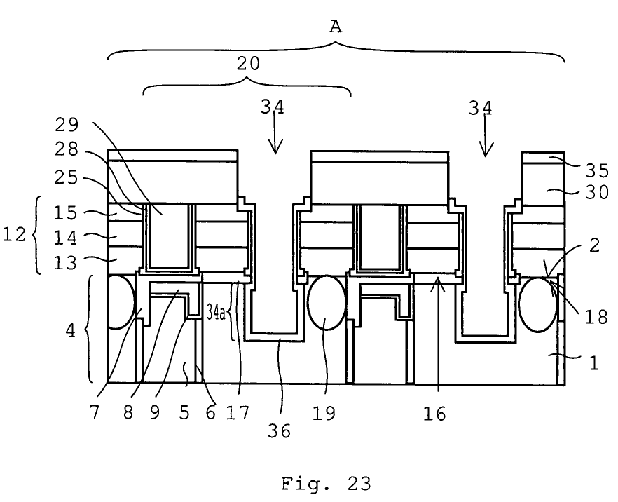

The silicon nitride layer 31 is structured and transformed to a hard mask 35. The optional layers 32, 33 may be used to transform a lithographically structured resist layer (not shown) into the hard mask 35. The hard mask 35 covers the support area B. There is provided a single opening 34 in the hard mask 31 for each memory cell 20 in the memory field area A. In a top view, the openings 34 are essentially placed in the middle between two neighbouring conductor lines 16 and essentially in the middle between two neighbouring isolation trenches 21. The lateral dimensions of the openings 34 may be larger than the distance between two neighbouring conductor lines 16, for instance about twice the distance between two neighbouring conductor lines 16. In other words, the lateral dimensions of the openings 34 may be larger than the minimal achievable lithographic resolution F, but small enough such that the openings 34 do not cover two neighbouring memory cells 20. For instance the lateral dimensions of the openings 34 may be at least about one and a half times the minimal achievable lithographic resolution F, at least about twice the minimal achievable lithographic resolution F, at most about two and a half times the minimal achievable lithographic resolution F, at most about two and a half times the minimal achievable lithographic resolution F. An exemplary arrangement of the openings 34 of the hard mask 35 is illustrated in the top view of FIG. 22.

The semiconductor device is further structured by means of the hard mask 35 and an etching process. The openings 34 of the hard mask 35 are transformed into the doped silica glass 30.

An alternative of the above method does not use a hard mask. The silica glass layer 30 is deposited such that the formed structure is fully covered.

Next, the silica glass layer 30 is structured, e.g. by means of a resist mask. Thus, a lithographic structuring process transforms a mask pattern directly into the doped silica glass layer 30. Instead of the doped silica glass an other suitable silicon oxide based material can be used.

The etching process is continued to remove the silica glass 29 or the other spin-on-dielectric provided in the gap between two neighbouring conductor lines 16. The etch reactants and the etching technique are chosen to react sufficiently selectively with silica glass and do basically not react with the materials of the covering layers 25, 29. Therefore, the cap layer 15 of the conductor lines 16 and the covering layers 25, 29 remain basically intact. There may be a loss of a few nanometres of the cap layer 15 and the covering layers 25, 29.

The conductor lines 16 are forming part of a masking structure complementary to the hard mask 35 for the subsequent etching processes. The selective etching processes are constricted to the narrow gaps between the conductor lines 16. The conductor lines 16 are, hence, forming a self aligned mask which limits one lateral dimension with respect to the mask 35.

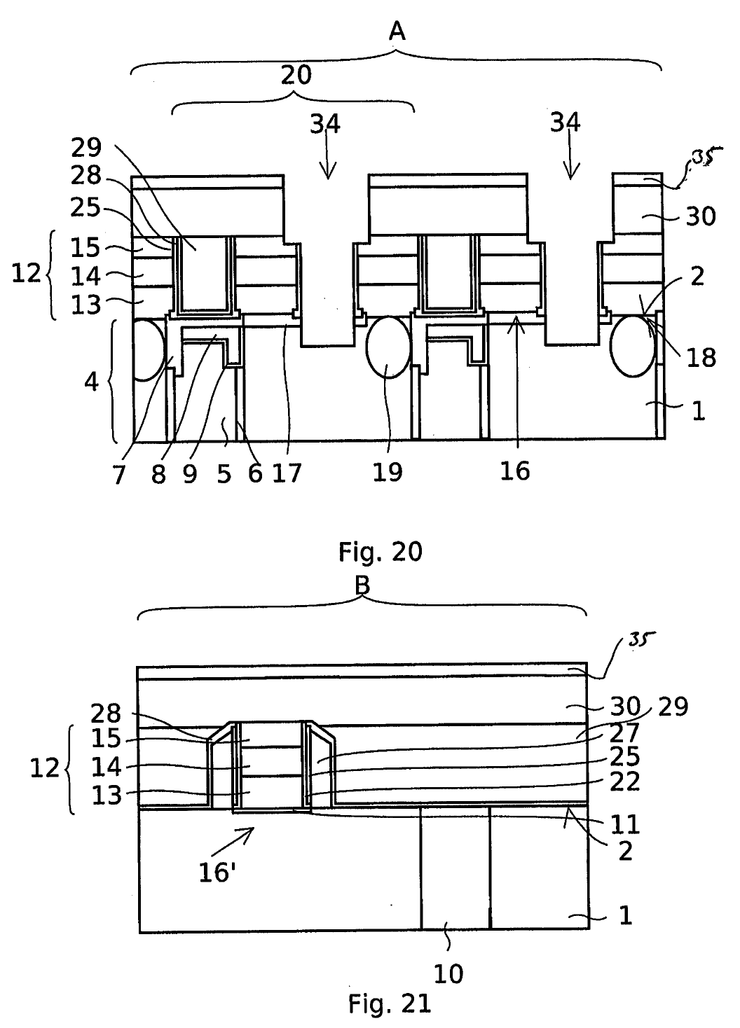

A trench is etched through the isolating layer 17 into the silicon substrate 1. The lateral dimensions of this trench are defined by the hard mask 35 and the distance of the conductor lines 16. Cross sections of the structure formed are illustrated in FIGS. 20 and 21 and a top view is shown in FIG. 22.

The high selectivity of the etching process of the doped silica glass 30, the silica glass 29, and an oxide isolation layer 17 and the silicon substrate 1 with respect to the covering layers 25, 28 and the cap layer 15 can be achieved by choosing the covering layers 25, 28 and the cap layer 15 to be made of silicon nitride, for instance. The etching process may be a reactive ion etching method using hydrofluoric gas as etching reactant.

The trench 34 can be widened and deepened in the substrate 1 by an isotropic etching step of the substrate 1. This newly created part the trench of 34 in the substrate 1 will be denoted collar trench 34a. An oxide layer 36 is grown on the surface of the collar trench 34a (FIG. 23), for instance by a low-pressure plasma radical oxidation step (LPRO). The nominal temperature of the plasma can be in the range of about 600° C. to 900° C., for example in the range of about 700° C. to 800° C., about 750° C. The LPRO step is applied for approximately at least 20 minutes up to two hours, for instance at least 30 minutes, at least 40 minutes, at the most one and half an hour, at the most one-hour, about 50 minutes. The oxide layer 36 formed has a thickness of approximately 5 to 12 nm, for instance at least 7 nm, at the most 10 nm, about 8 nm.

The LPRO step applied can form the oxide layer 36 on the covering layers 25, as well. The oxide layer 36 in the area of the covering layers 25 may be thinner compared to the oxide layer 36 in the collar area 34a. The oxide layer 36 may be made of silicon oxide.

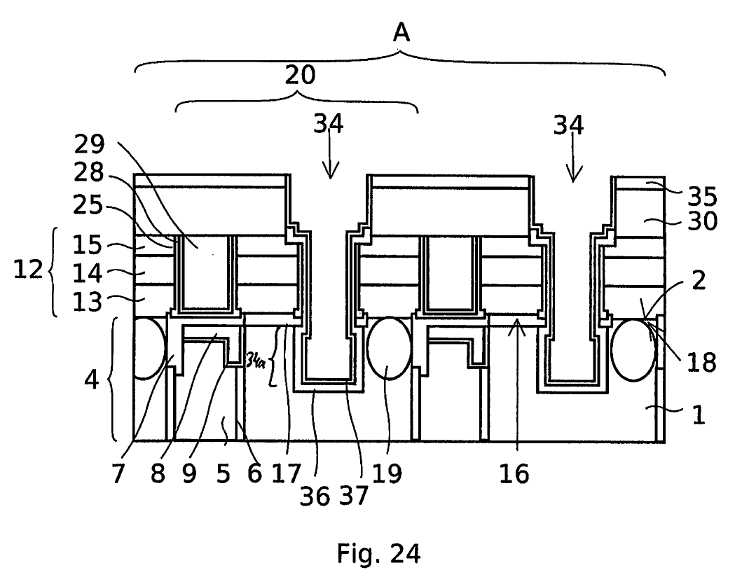

On the oxide layer 36 a nitride layer 37 is grown (FIG. 24). The nitride layer 37 may have a thickness of approximately 3 to 8 nm, for instance 4 nm to 6 nm, about 5 nm.

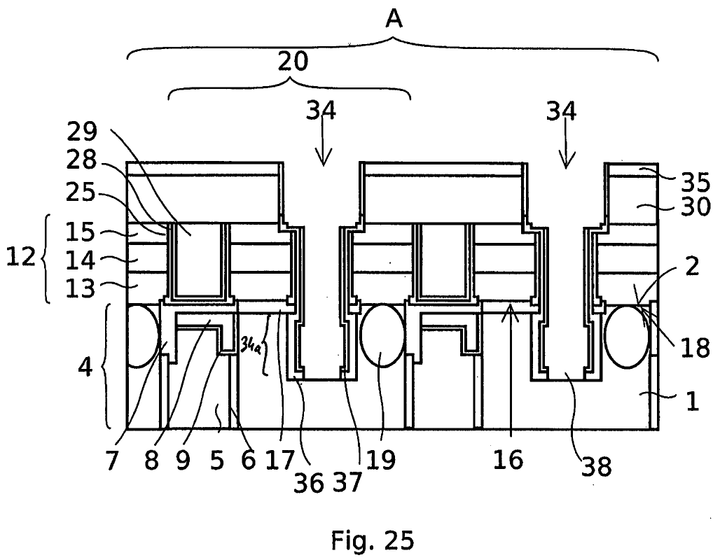

The oxide layer 36 and the nitride layer 37 are removed from the bottom part of the trench 34 (FIG. 25). This can be achieved by an anisotropic reactive ion etching process. Thus, the substrate 1 is laid open or exposed due to an opening 38 at the bottom of the trench 34.

The covering layers 25, 28 are protecting the conductor lines 16 against the anisotropic reactive ion etching process due to their sufficient thickness.

A selective isotropic etching process may be performed which reacts with silicon but not with silicon nitride. Hence, the nitride layer 37 protects the side walls of the collar trench 34a. The isotropic etching process reacts only with the substrate 1 and, therefore, extends the trench 34 beyond a collar trench 34a into the substrate 1. The newly created part of the trench 34 which is arranged below the collar trench 34a will be denoted as active area trench 39. Subsequently, any remaining oxide on the substrate 1 in the area of the active area trench 39 is removed by an isotropic oxide etch step, for example by a wet etching process.

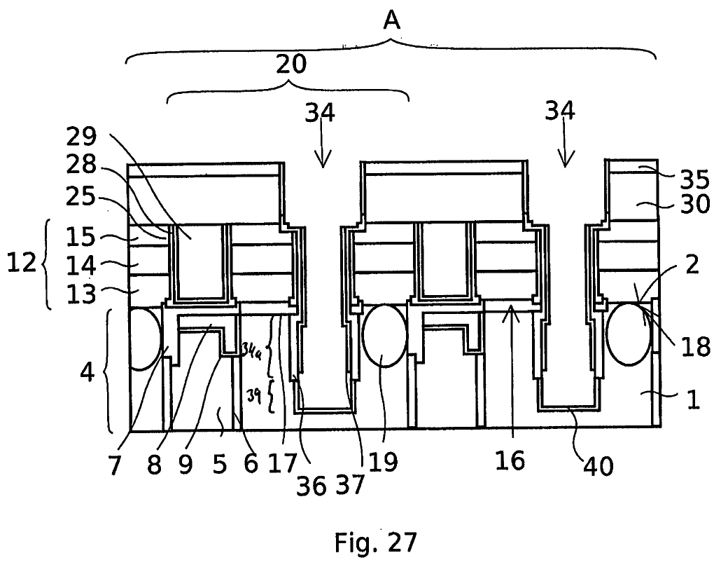

An LPRO step may be applied to form a gate oxide layer 40 on the side walls of the active area trench 39 (FIG. 27). The nominal temperature of the plasma can be in the range of about 600° C. to 900° C., for instance in the range of about 700° C. to 800° C., about 750° C. The LPRO step is applied for approximately at least 5 minutes up to one hour, for instance at least 10 minutes, at least 15 minutes, at the most 40 minutes, at the 30 minutes, about 20 minutes. The gate oxide layer 40 formed has a thickness of approximately 1 to 5 nm, for instance at least 2 nm, at the most 4 nm, about 3.5 nm.

The trenches 34 are filled with highly doped polycrystalline silicon 41. A dopant material can be applied into a reaction chamber during the deposition of the polycrystalline silicon such that in situ doped polycrystalline silicon 41 is formed. The polycrystalline silicon plugs 41 form gate electrodes for selection transistors of the memory cells 20. The conductive path between the inner electrode 5 and the conductive part 14, 15 of a conductor line 16 is controlled by a gate channel established in the substrate 1 along the gate dielectric layer 40.

The trench 34 comprises four different sections along its vertical extension. The lowest section (deepest in the substrate 1), denoted as active area trench 39, is provided with a gate oxide 40 along the side walls. This section defines the gate area of an active device. The highly doped polycrystalline silicon 41 is the gate electrode. The collar trench 34a which is arranged above the active area trench 39 is provided with a thick dielectric isolation 36, 37. Thus, the polycrystalline silicon plug 41 is electrically isolated from the substrate 1 in this area. In the third section between the conductor lines 16, the width of the trench 34 and, hence, the polycrystalline silicon plug 41 is defined by the distance between the conductor lines 16. The remaining parts of the covering layers 25, 28 are sufficiently isolated the conductor lines 16 from the polycrystalline silicon plug 41. The topmost part of the trench 34 is purely defined by the hard mask 34.

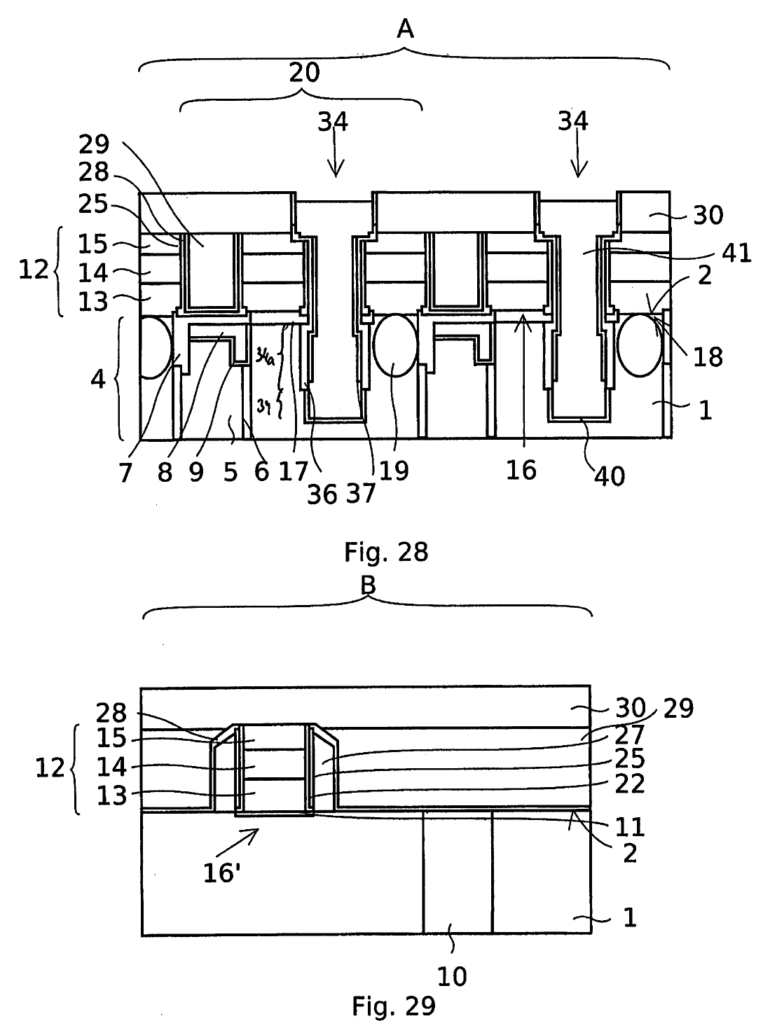

Polycrystalline silicon 41 deposited on the hard mask 35 may be removed by a non-selective chemical recess step. Consecutively, the hard mask 35 can be stripped off (FIGS. 28 and 29).

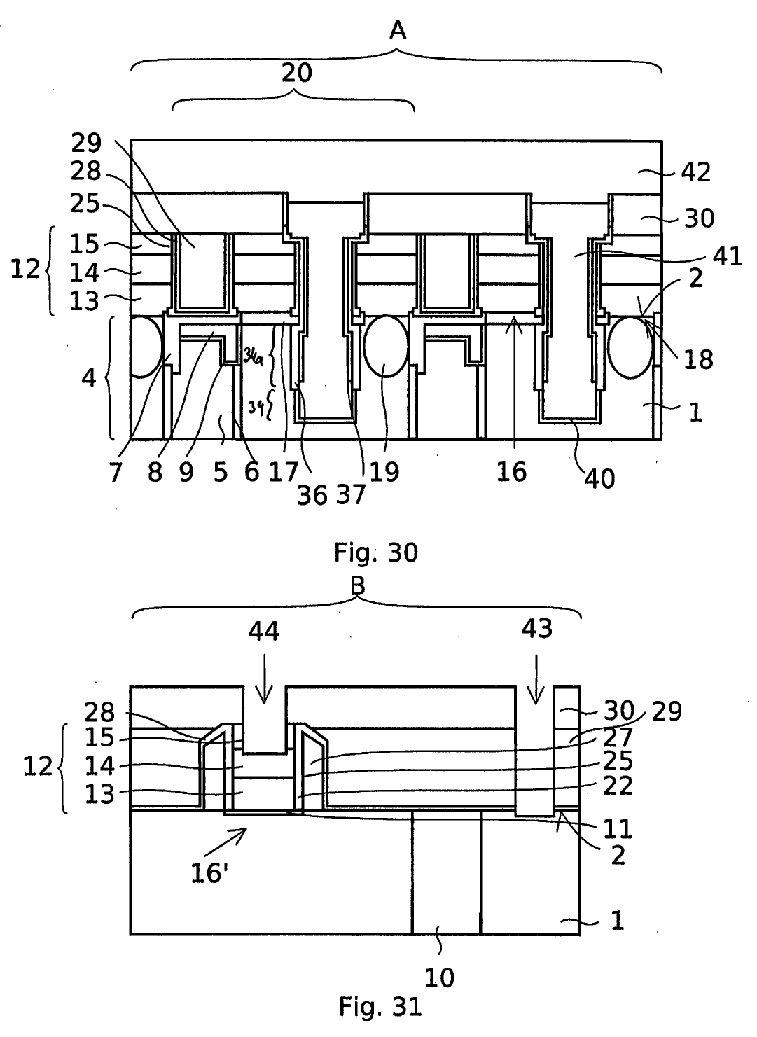

A block mask 42 selectively covers the memory field areas A. Contact openings 43 and 44 are formed in the support area B in order to contact the substrate 1 and/or the gate stacks 16′ (FIGS. 30 and 31). The cap layer 15 can be removed by an etching process etching selectively silicon nitride with respect to silica glass 30.

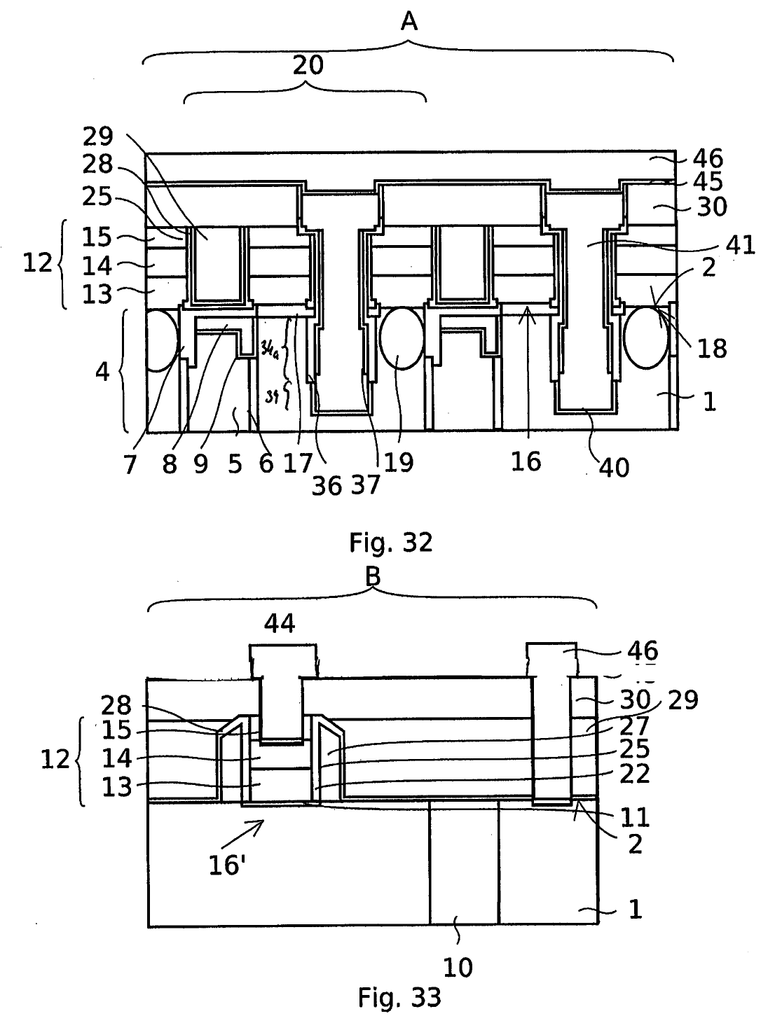

Word-lines 46 are formed and structured in the memory field area A and the support area B. The word-lines 46 can be made of tungsten, for instance. Tungsten can be deposited by a chemical vapour deposition and structured by means of a reactive ion etching method. A barrier layer 45 of titanium or titanium nitride can be deposited prior to the deposition of the word-lines 46 (FIGS. 32 and 33).

In the above embodiment the capacitor structure has been preformed into at the substrate 1 preceding the formation of an active device, for example selection transistor, in each of the memory cells 20. In another embodiment the capacitor structure is just partially preformed, in particular the deep trench has been etched yet. A sacrificial plug is provided to close the collar region 4. Subsequent to the formation of the active device, as for instance illustrated in the above embodiment, the sacrificial plug can be removed and the formation of the capacitor structure be finished.

### Second Embodiment

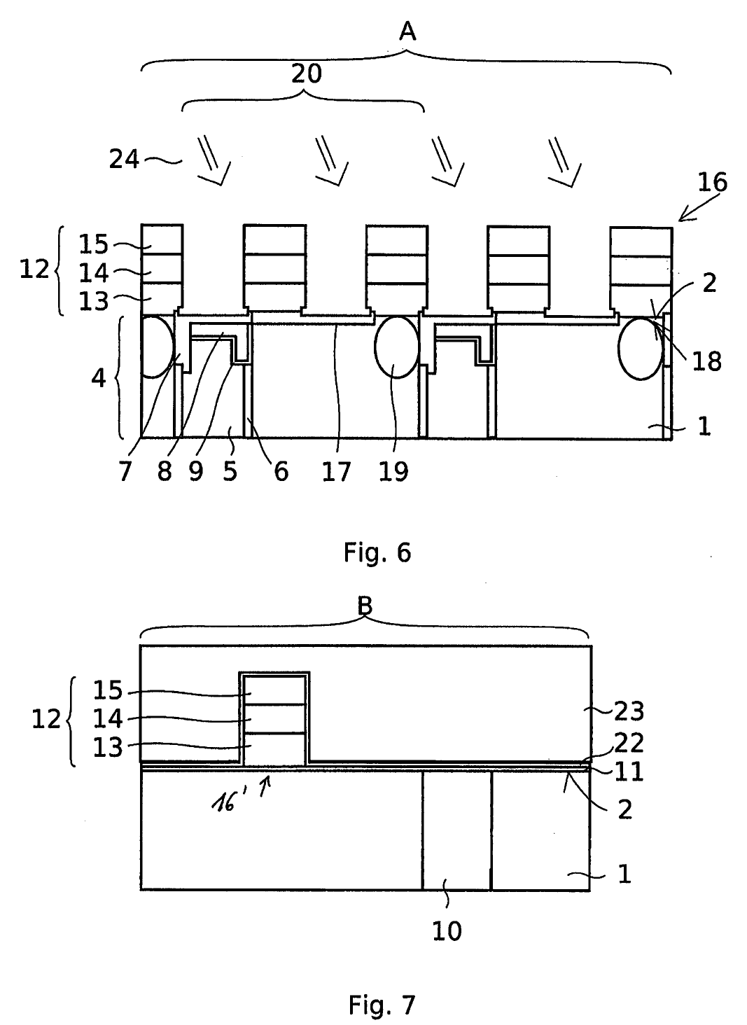

A second embodiment of a method for forming an integrated circuit having an active semiconductor device will be explained wherein reference is made to processing steps of the first embodiment. The initial processing steps of the second embodiment can be performed according to the initial processing steps of the first embodiment explained along with FIGS. 1 to 7. The starting point for the below explanations is the structure shown in the drawings of FIGS. 6 and 7.

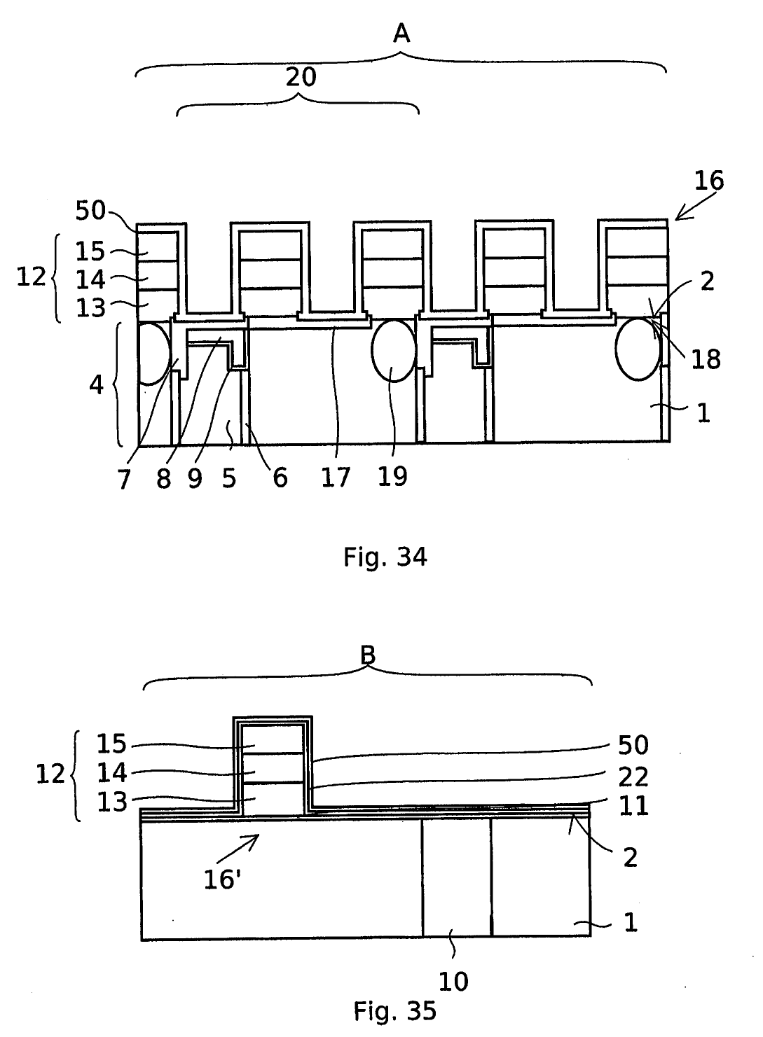

A covering layer 50 is deposited on the conductor lines 16 in the memory field area A and on the gate stack 16′ in the support area B (FIGS. 34 and 35). The covering layer 50 may be formed of silicon nitride or silicon oxynitride. The covering layer 50 has a thickness which is significantly smaller than the distance between two neighbouring conductor lines 16, for instance less than a third of the distance between two neighbouring conductor lines 16. The thickness of the covering layer 50 may be in the range of about 7 nm to 15 nm, for instance about 10 nm to 12 nm, about 10 nm.

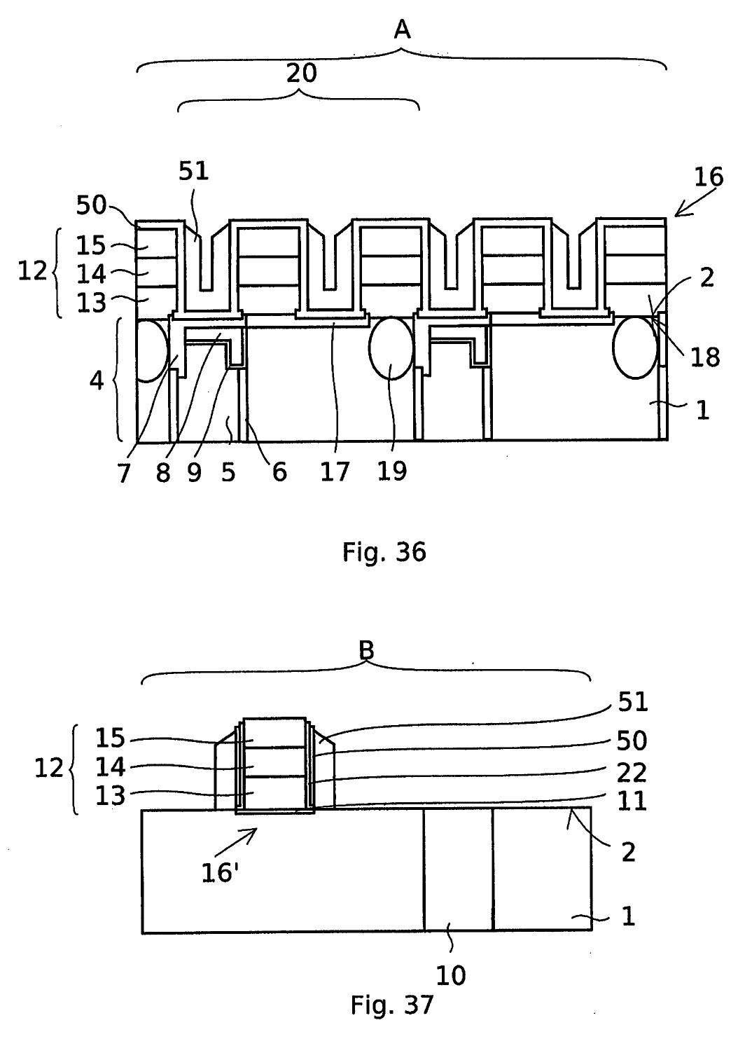

A spacer layer 51 may be deposited in the memory field area A and the support area B (FIGS. 36 and 37). The thickness of the spacer layer 51 is approximately 20% to 40% of the distance between neighbouring conductor lines 16. Hence, the spacer layer 51 does not completely fill the gap between neighbouring conductor lines 16. An exemplary thickness may be in the range of about 20 to 40 nm, about 25 to 35 nm, about 30 nm. The spacer layer 51 may be made of or comprise silicon oxide. The silicon oxide spacer layer 51 can be deposited by a low pressure TEOS process. Other suitable deposition techniques can be employed, too. The spacer layer 51 is anisotropically etched such that vertical dimension of the spacer layer 51 is nominally reduced by a thickness larger than the thickness of the spacer layer 51 previously deposited. Thus, the spacer layer 51 just remains along the side walls of the gate stack 16′ and the side walls of the conductor lines 16.

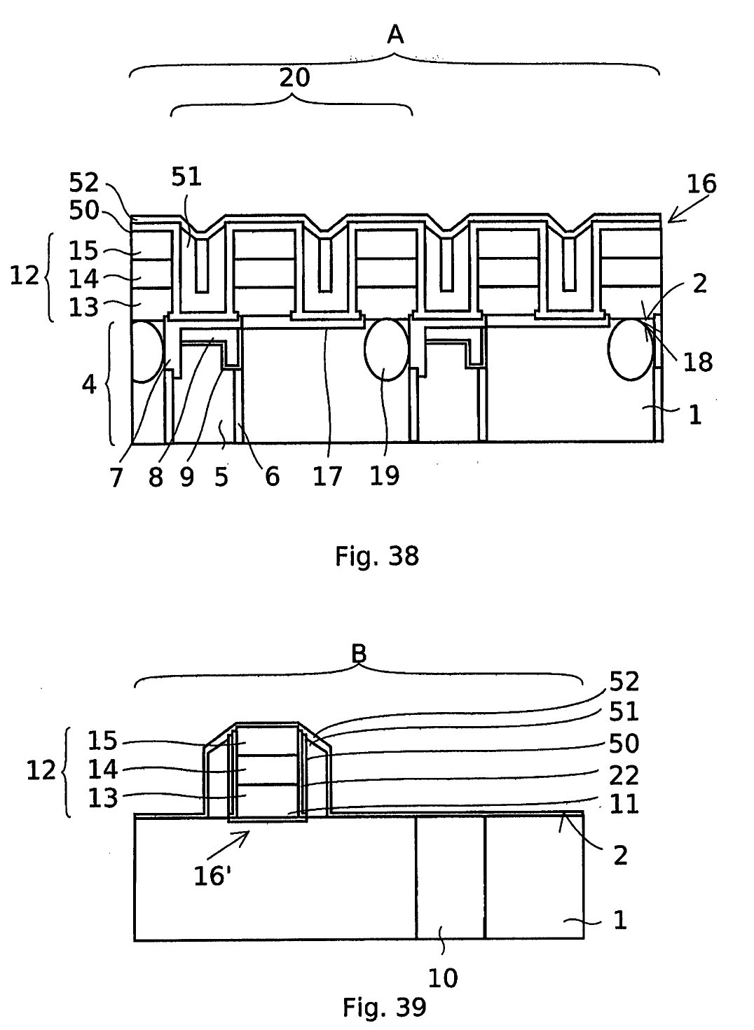

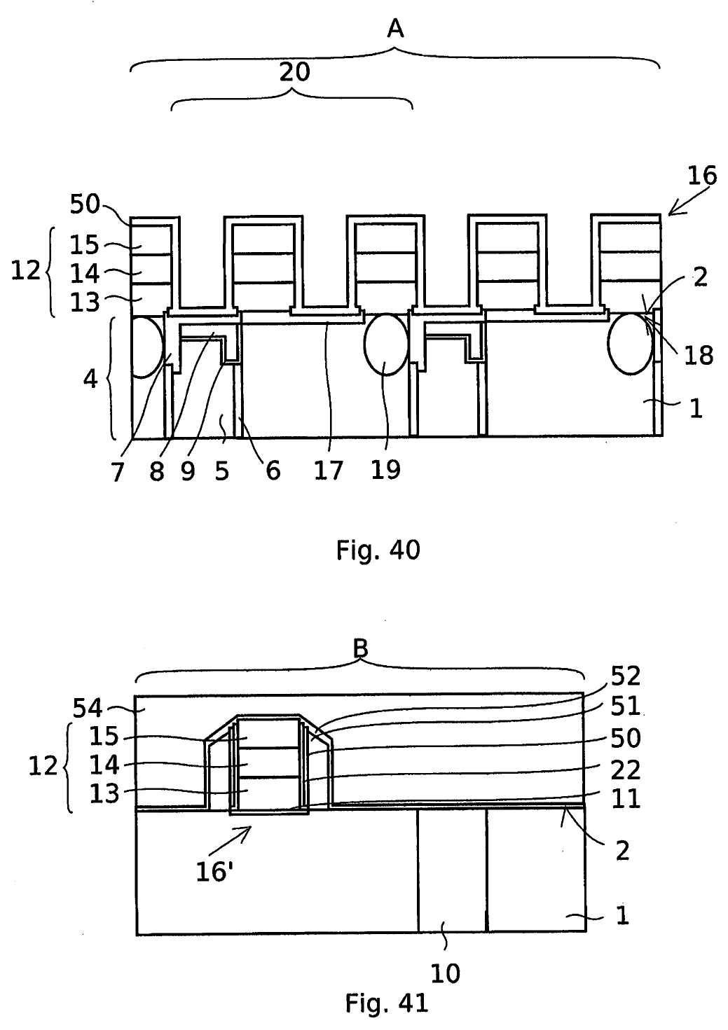

A second covering layer 52 is deposited in the memory field area A and the support area B (FIGS. 38 and 39). The second covering layer 28 may be deposited such that a mechanical stress is applied to the underlying layers, in particular to the gate stack 16′ and a gate channel area below the gate stack 16′. The thinned spacer layer 27, the (first) covering layer 50, and the thin liner layer 22 essentially transmit the stress to the gate stack 16′.

Subsequently, a block mask 54 selectively covers the support area B. The second covering layer 52 is removed by an etching process. The spacer layer 51 is removed between the conductor lines 16 by a selective etching process. The obtained structure is shown in FIGS. of 40 and 41. Afterwards, the block mask 54 can be stripped.

A spin-on-dielectric is deposited or spun on in the support area B and the memory field area A alike the processing steps illustrated by FIGS. 16 and 17 of the first embodiment. The subsequent processing steps of the first embodiment are performed by the second embodiment, too.

### Third Embodiment

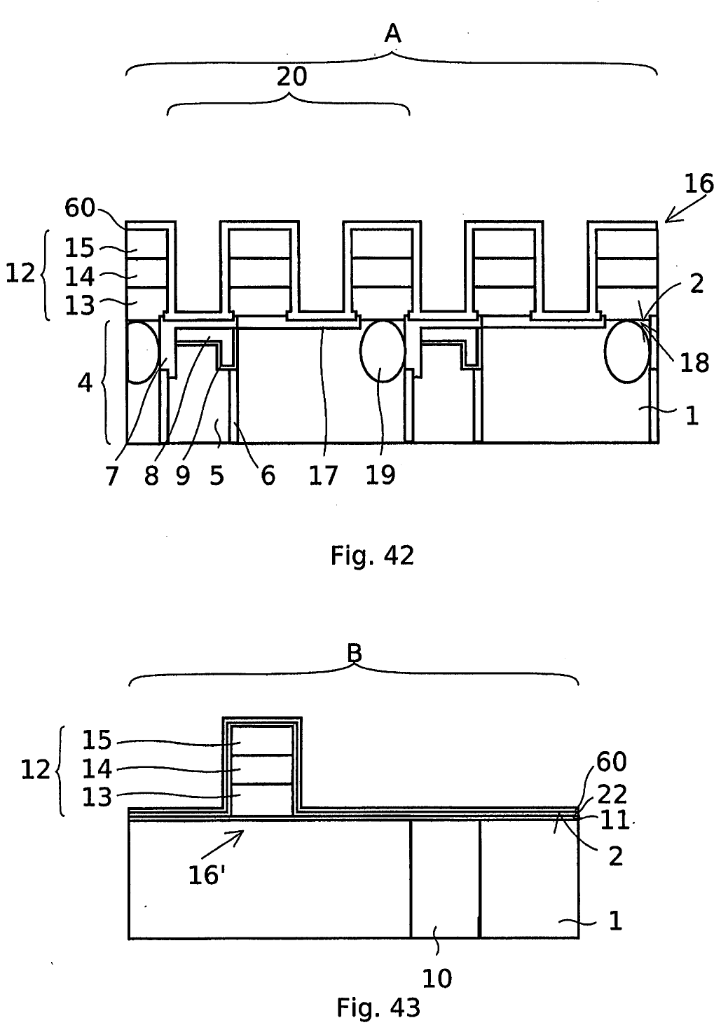

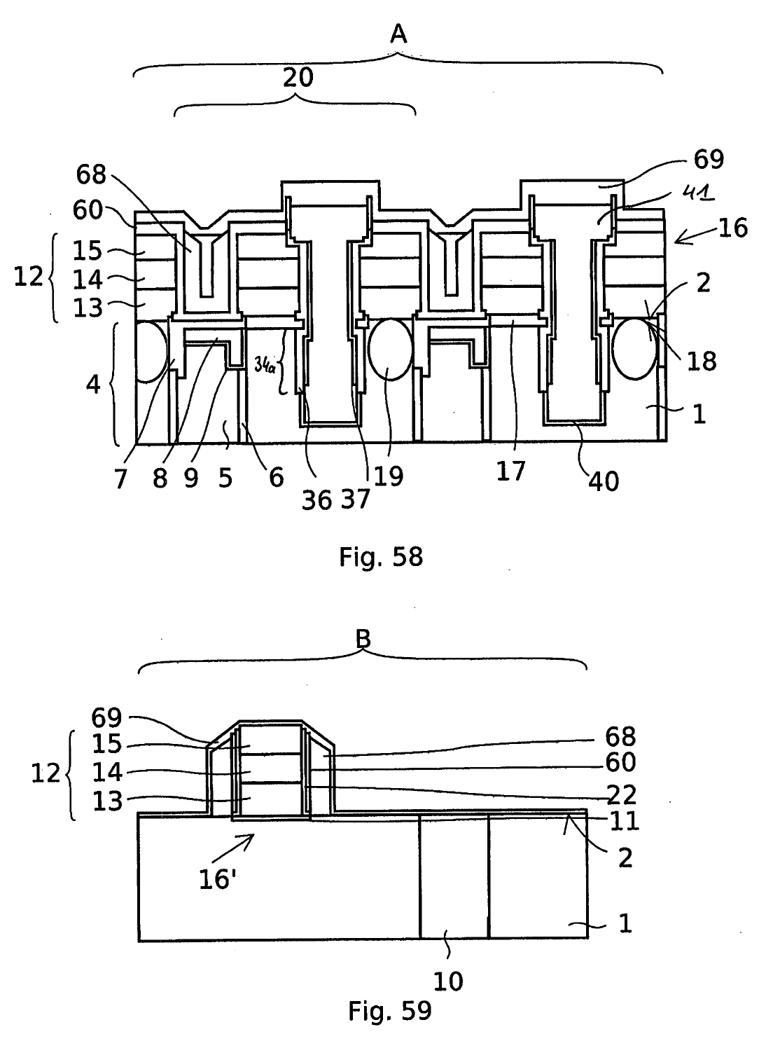

A third embodiment for forming an integrated circuit having an active semiconductor device will be demonstrated making reference to FIGS. 42 to 67. A preprocessed wafer or substrate 1 may be provided alike in the first and second embodiment and as illustrated in FIGS. 1 to 7. A staple 12 of conductive layers 13, 14 and a cap layer 15 are deposited on the surface 2 of the substrate 1. By a single lithographic structuring process the staple 12 is formed into conductor lines 16 in the memory field area A and into gate stacks 16′ in the support area B (see partial cross sections in FIGS. 42 and 43; a top view is shown in FIG. 3). The cap layer 15 can be made of or comprise silicon nitride. Reference is made to the explanations given with the first embodiment and FIGS. 1 to 7 for further details of FIGS. 42 and 43.

A covering layer 60 is deposited on the conductor lines 16 in the memory field area A and on the gate stack 16′ in the support area B (FIGS. 42 and 43). The covering layer 60 may be formed of silicon nitride or silicon oxynitride. The covering layer 60 has a thickness which is significantly smaller than the distance between two neighbouring conductor lines 16, for instance less than a third of the distance between two neighbouring conductor lines 16. The thickness of the covering layer 50 may be in the range of about 7 nm to 15 nm, for instance about 10 nm to 12 nm, about 10 nm.

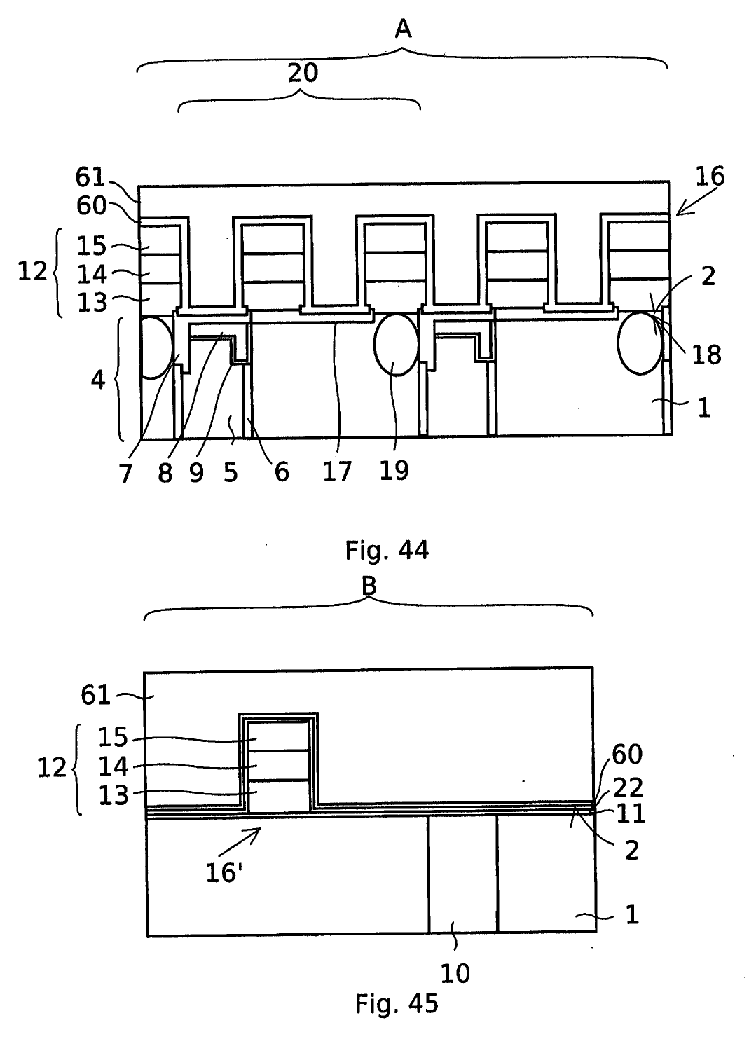

A spin-on-dielectric 61 is spun on or deposited on the covering layer 60 (FIGS. 44 and 45). The spin-on-dielectric 61 fills the gaps (spacings) between the conductor lines 16. The spin-on-dielectric 61 is provided of a sufficient thickness such that the conductor lines 16 and the gate stacks 16′ are completely covered. A high temperature annealing process is applied in order to remove voids and to densify the spin-on-dielectric 61. The spin-on-dielectric 61 may be chemically mechanically polished. The chemical mechanical polishing step can be performed for a specified duration. An endpoint control is not necessary.

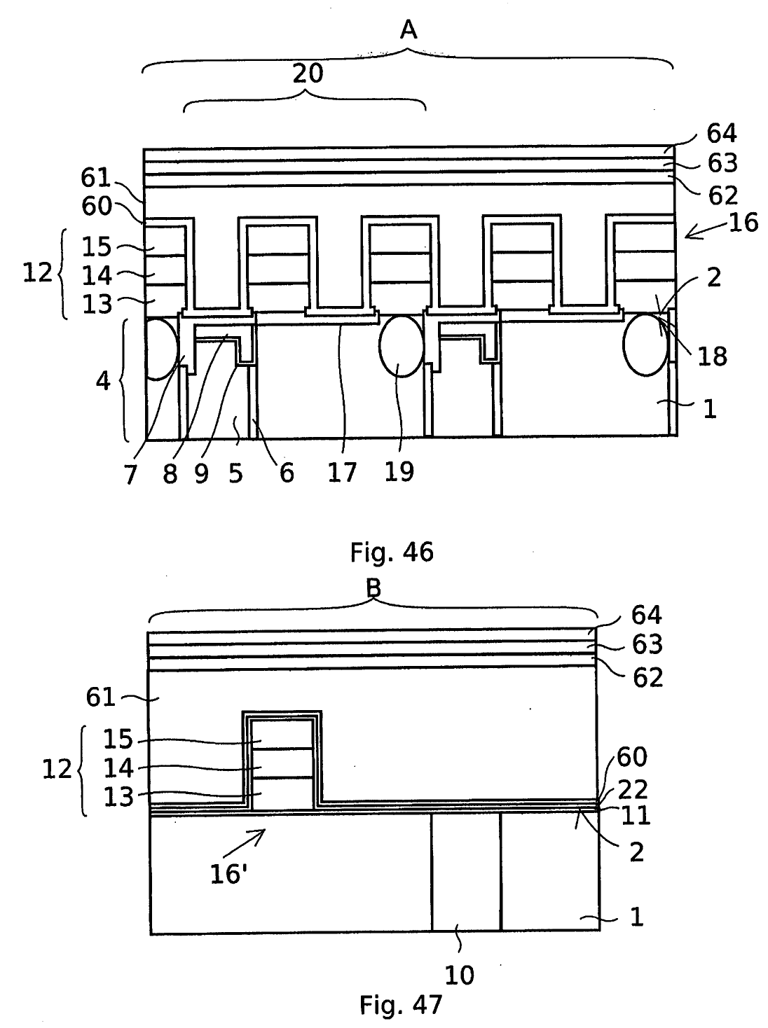

A stack of a silicon nitride layer 62 and masking layers 63 and 64 are deposited on the spin-on-dielectric 61 (FIGS. 46 and 47). The masking layers 63 and 64 may be made of carbon silicon and silicon oxynitride, respectively.

The silicon nitride layer 62 is structured and transformed to a hard mask 65 by means of the masking layers 63 and 64. Other techniques for forming a hard mask 65 can be applied, too.

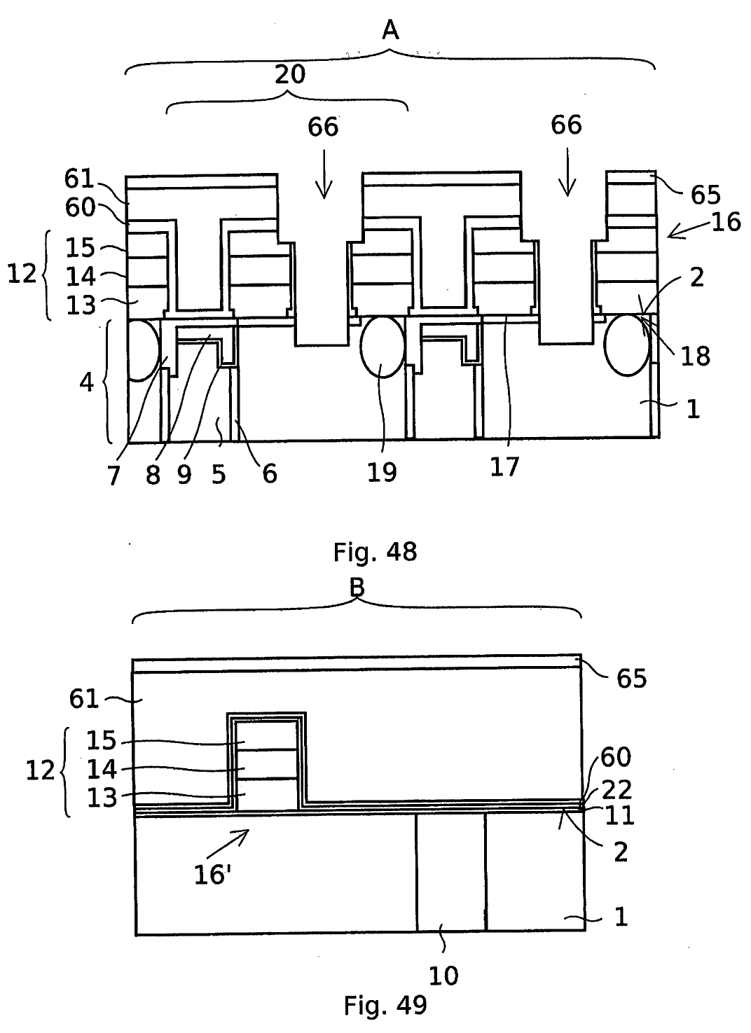

The hard mask 65 may be provided with a single opening above each of the memory cells 20 (see FIGS. 48 and 49). The openings are arranged essentially above the spacing between two neighbouring conductor lines 16. The diameter or width of the openings exceeds the distance between the two neighbouring conductor lines 16. The diameter of the openings can be up to three times as large as the distance between the two neighbouring conductor lines 16, for instance at least 2½ times, at least twice, about twice, at least 1½ times the distance. The diameter or width of interest is to be measured orthogonal to the arrangement of the conductor lines 16. The support area B remains fully covered by the hard mask 65.

The hard mask 65 may be used for a subsequent selective etching method. The reactants of the selective etching method are chosen to react with the spin-on-dielectric, but basically not with the covering layer 60 (and the hard mask 65). The spin-on-dielectric is removed by an etching rate which by far exceeds the etching rate of the covering layer 60, for instance at least five times or at least by a magnitude. As an example for a reactant, hydrofluoric gas/plasma can be used in an anisotropic reactive ion etching process.

Trenches 66 may be etched through the spin-on-dielectric 61 into the substrate 1 by means of this selective etching method (FIGS. 48 and 49). The pattern of the hard mask 65 is transformed into the spin-on-dielectric 61 in the area above the conductor lines 16. The spin-on-dielectric 61 is essentially completely removed from the spacing between the two neighbouring conductor lines 16 and exposed by the opening of the hard mask 65.

The isolating layer 17, if present, is exposed to the reactants of the selective etching method. An opening is etched through the isolating layer 17. This can be achieved by the same selective etching method. The isolating layer 17 can be made of silicon oxide. The selective etching method can be chosen to be selective with respect to the materials of the isolating layer 17, too. This holds especially true, if the spin-on-dielectric 61 is made of silicon oxide or silica glass.

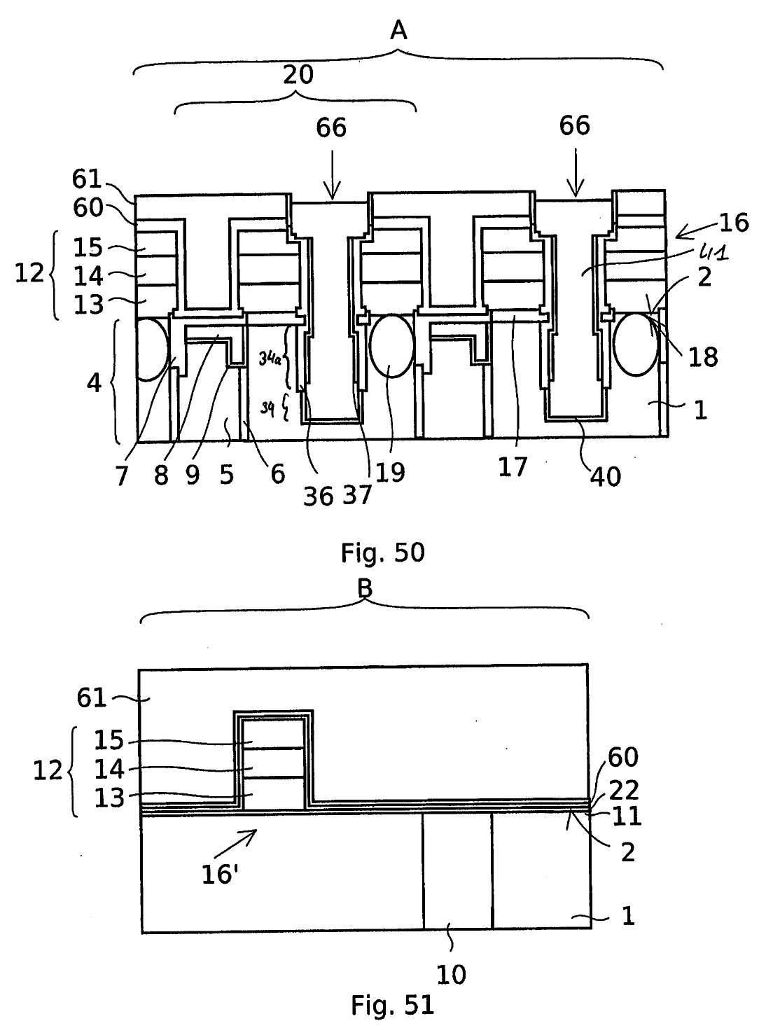

The substrate 1 is exposed by the trench 66. A selective etching process may be used to deepen the trench 66 and to form a trench, comprising a collar trench 34a and an active area trench 39, in the substrate 1 (FIGS. 50 and 51). A gate oxide 40 is grown on the surface of the active area trench 39. Identical or similar processing steps as the ones explained along with FIGS. 22 to 29 can be performed to form the collar trench 34a, the active area trench 39, and the gate oxide 40.

The covering layer 60 is only slightly thinned along the side walls of the conductor lines 16. There may be a partial removal of the covering layer 60 and the cap layer 15 of the conductor lines 16 in the range of some nanometres. The conductive layers 13, 14 of the conductor lines 16 nevertheless remain fully covered by the covering layer 60 and the cap layer 15.

The trench 66 may be filled with conductive polycrystalline silicon 41, for example highly doped polycrystalline silicon or any other suitable conductive material. An etching process is applied for the period sufficient to remove any polycrystalline silicon from the top of the spin-on-dielectric 61. The etching process can be chosen to selectively etch the polycrystalline silicon 41 versus the spin-on-dielectric 61. FIGS. 50 and 51 are illustrating an example of a semiconductor memory structure manufactured so far.

The hard mask 65 is stripped off before or after the fill-in of the polycrystalline silicon 41.

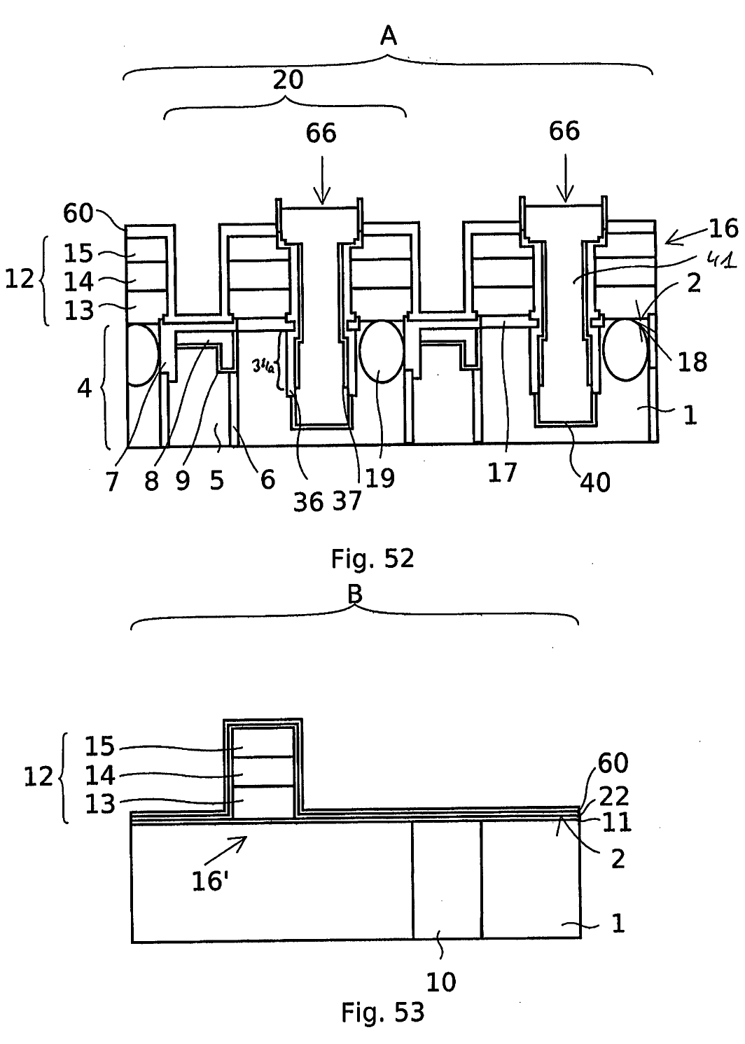

Consecutively, the spin-on-dielectric 61 is stripped off in the memory field area A and the support area B (FIGS. 52 and 53).

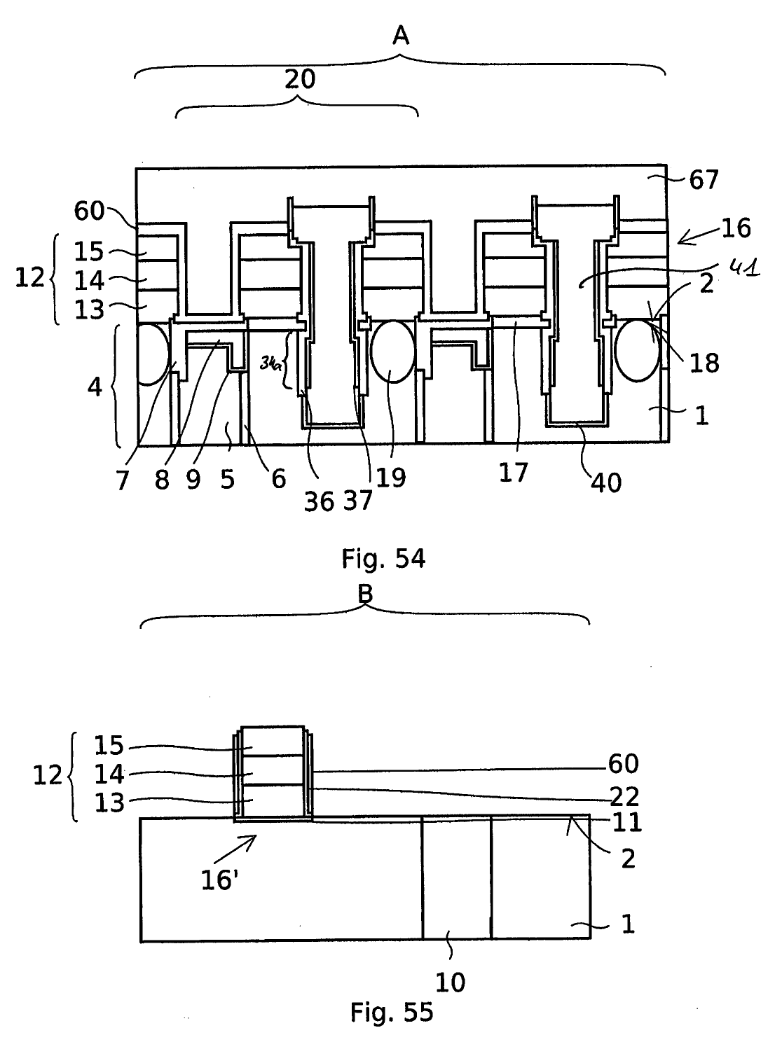

A block mask 67 is provided to protect the memory field area A. An anisotropic etching process is applied to the support area B by which means the gate dielectric 11, the liner layer 22, and the covering layer 60 are removed from the surface 2 of the substrate 1. The vertical parts of the liner layer 22 and the covering layer 60 remain along the side walls of the gate stack 16′ (FIGS. 54 and 55). Dopant materials can be implanted into the substrate 1, for instance to form source and drain areas (not shown) in the support area B. The block mask 67 is stripped off consecutively.

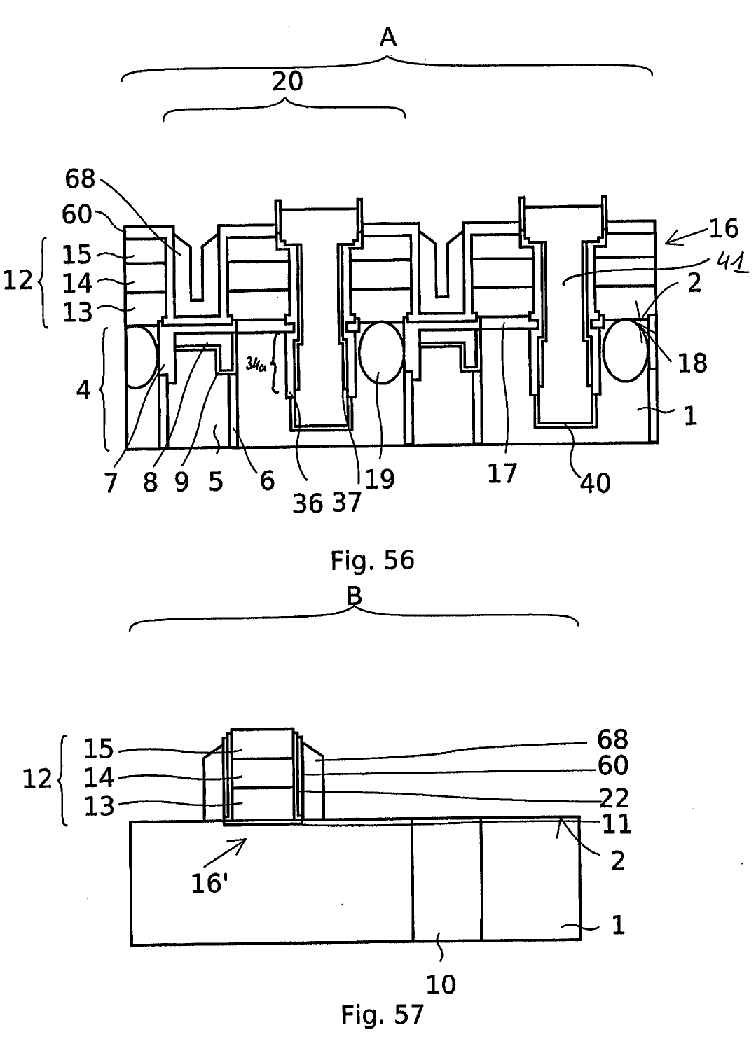

A spacer layer 68 is deposited over the whole substrate 1. The thickness of the spacer layer 68 is for example 20% to 40% of the distance between neighbouring conductor lines 16. Hence, the spacer layer 68 does not completely fill the gap between neighbouring conductor lines 16. An exemplary thickness may be in the range of about 20 to 40 nm, about 25 to 35 nm, about 30 nm. The spacer layer 68 may be made of or comprise silicon oxide. The silicon oxide spacer layer 68 can be deposited by a low pressure TEOS process. Other suitable deposition techniques can be employed, too. The spacer layer 68 is anisotropically etched such that vertical dimension of the spacer layer 68 is nominally reduced by a thickness larger than the thickness of the spacer layer 68 previously deposited in the support area B. Thus, the spacer layer 68 just remains along the side walls of the gate stack 16′ and the side walls of the conductor lines 16 (FIGS. 56 and 57).

Further dopant materials can be implanted into the substrate 1, for instance to form second parts of source and drain areas into the previously formed source and drain areas. The second parts can have a different dopant concentration, for instance higher dopant concentration, than the previously formed source and drain areas.

The spacer layer 68 may be thinned by an isotropic etching process. The spacer layer 68 may be thinned by at least 5 nm, for instance at least 10 nm, at least 15 nm, at the most 20 nm. A silicidation of the substrate in the area of the recessed spacer can be performed. At least one of titan silicide, cobalt silicide, and nickel silicide can be formed to provide low ohmic contact areas.

A stress layer 69 or strained layer is deposited in both the memory field area A and the support area B. The stress layer 69 may comprise or be made of silicon nitride. The thickness of the stress layer 69 can be in a range 5 nm to 30 nm, for instance 7 nm to 25 nm, 10 nm to 20 nm, about 5 nm.

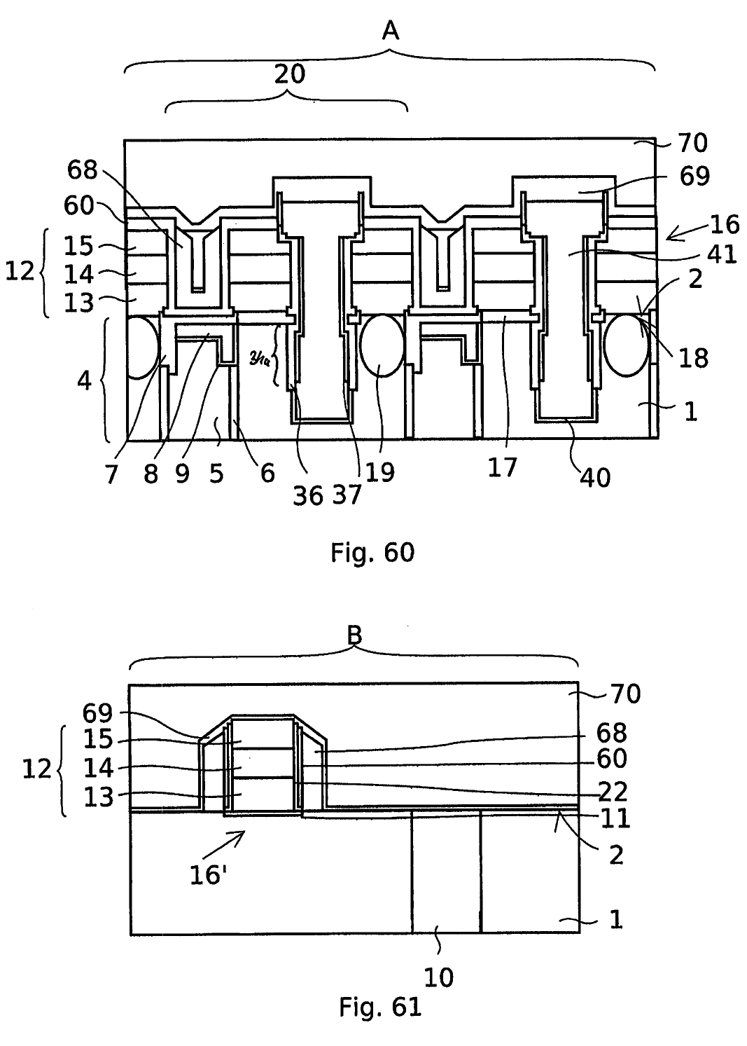

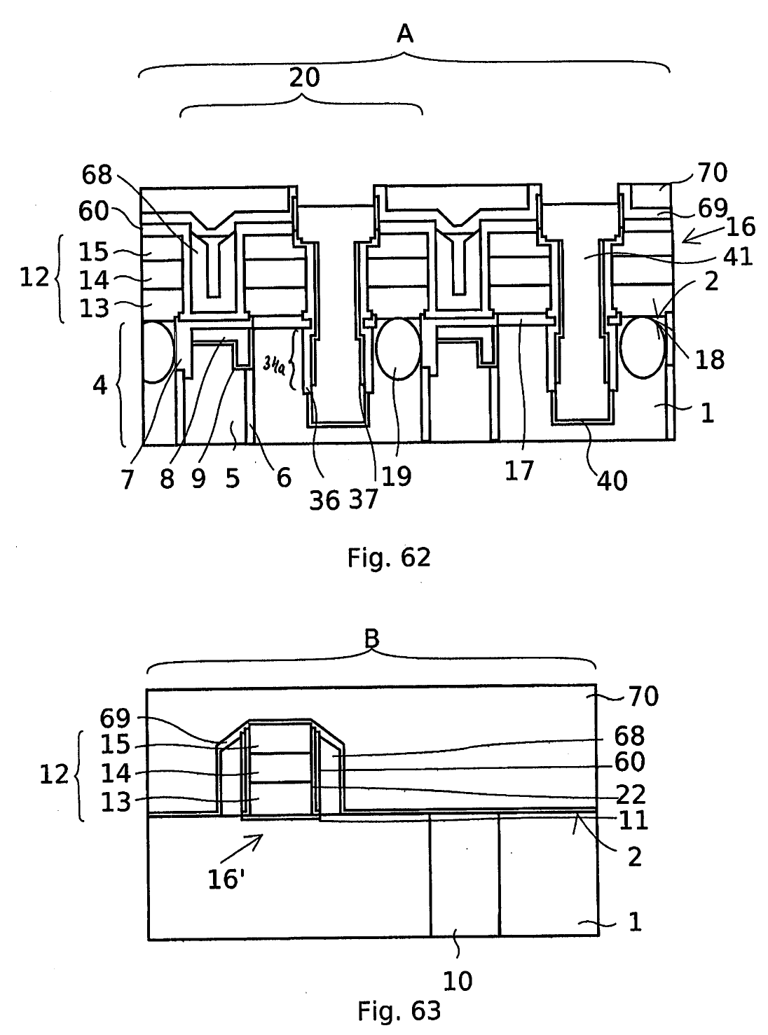

A spin-on-dielectric 70, for instance spin on glass, is deposited on the whole substrate 1 (FIGS. 60 and 61). The spin-on-dielectric may be annealed by a high-temperature annealing step. A blind polishing step can be applied to remove the spin-on-dielectric 70 above the polycrystalline silicon plug 41. The polishing step can include a chemical mechanical polishing which is not selective with respect to the spin-on-dielectric 70 and the polycrystalline silicon 41. The exposed polycrystalline silicon 41 may be optionally recessed by a selective etching process. The top surface of the polycrystalline silicon plug 41 is therefore closer to the surface 2 than the top surface of the spin-on-dielectric 70 (see FIGS. 62 and 63).

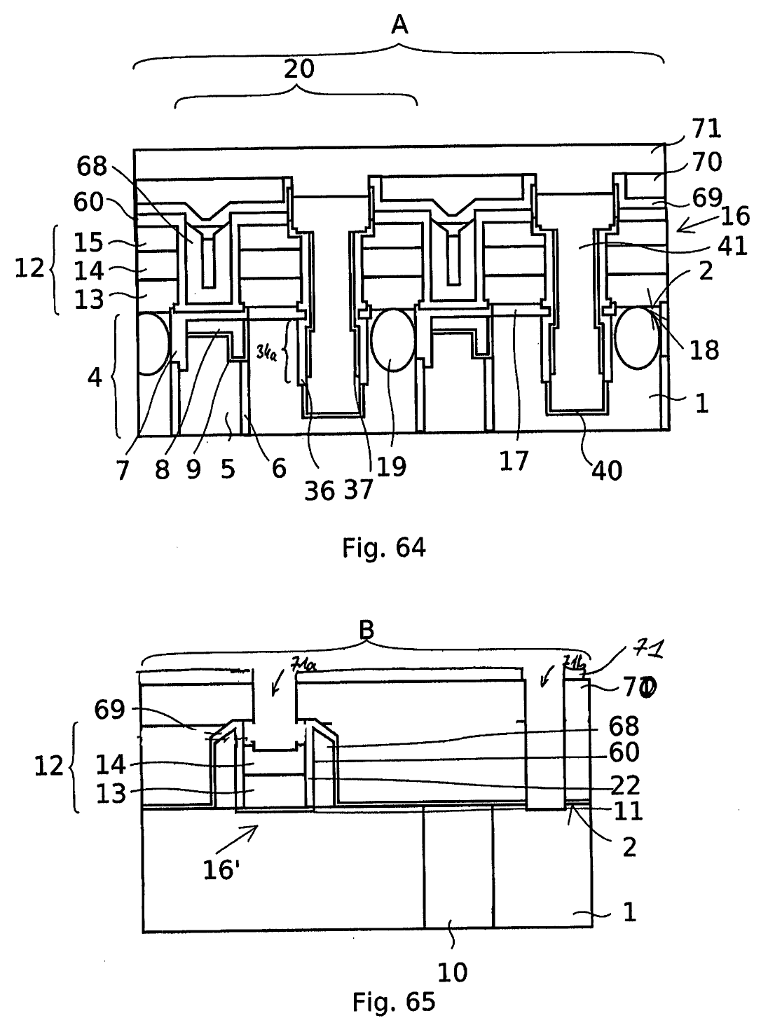

Openings 71a and 71b are formed into the spin-on-dielectric 70 in the support area B for defining contact openings into the substrate 1 and the gate stack 16′. A respective mask 71 may be provided (FIGS. 64 and 65). The openings 71a and 71b can be etched in a two-step process. In a first step, etching reactants are used which selectively etch the spin-on-dielectric 70 with respect to the stress layer 69 and the cap layer 15. The first step is self terminated, when the openings 71a and 71a reach the covering stress layer 69. In the second step, etching reactants are used which selectively etch the cap layer 15 and the stress layer 69 with respect to the spin-on-dielectric 70. The cap layer 15 is removed and the conductive layer 14 is exposed by the opening 71a. Further, the substrate 1 is exposed by the opening 71b. Materials of the stress layer 69 and the cap layer 15 can comprise or be made of silicon nitride, wherein the spin-on-dielectric 70 may comprise or be made of spin on glass, silicon oxide or other suitable materials. Etching reactants for the first step can be based on a fluorine comprising gas. Etching reactants for the second step can be based on phosphoric acid, for example.

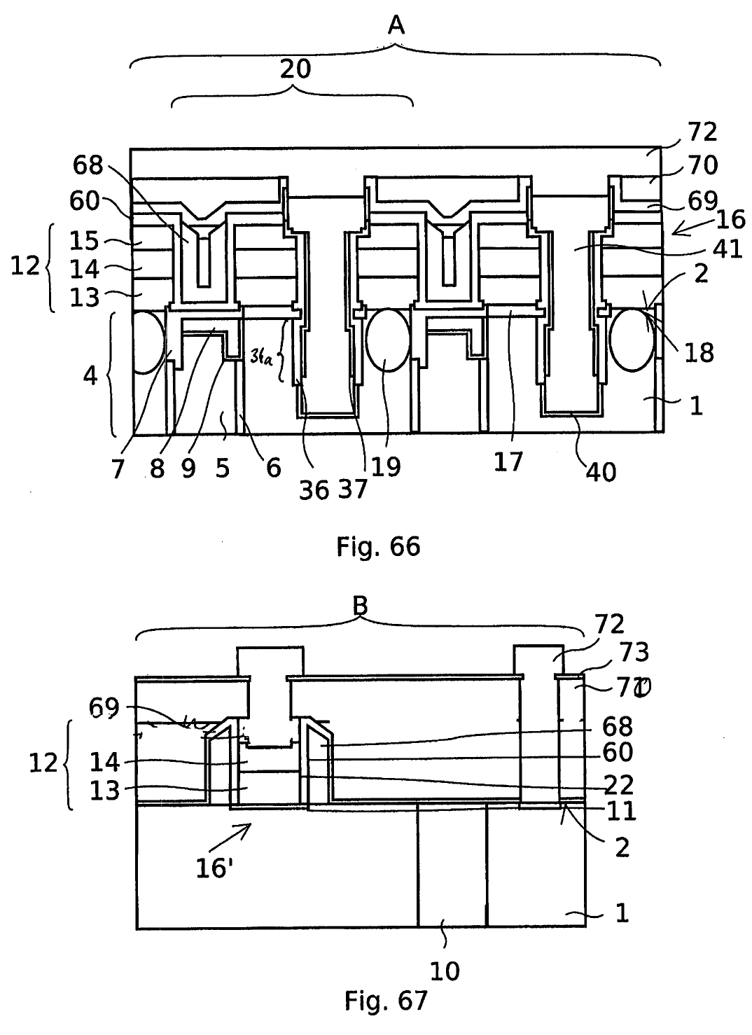

Word-lines 72 are formed and structured in the memory field area A and the support area B. The word-lines 72 can be made of tungsten, for instance. Tungsten can be deposited by a chemical vapour deposition technique and structured by means of a reactive ion etching method. A barrier layer 73 of titanium or titanium nitride can be deposited prior to the deposition of the word-lines 72 (FIGS. 66 and 67).

### Forth Embodiment

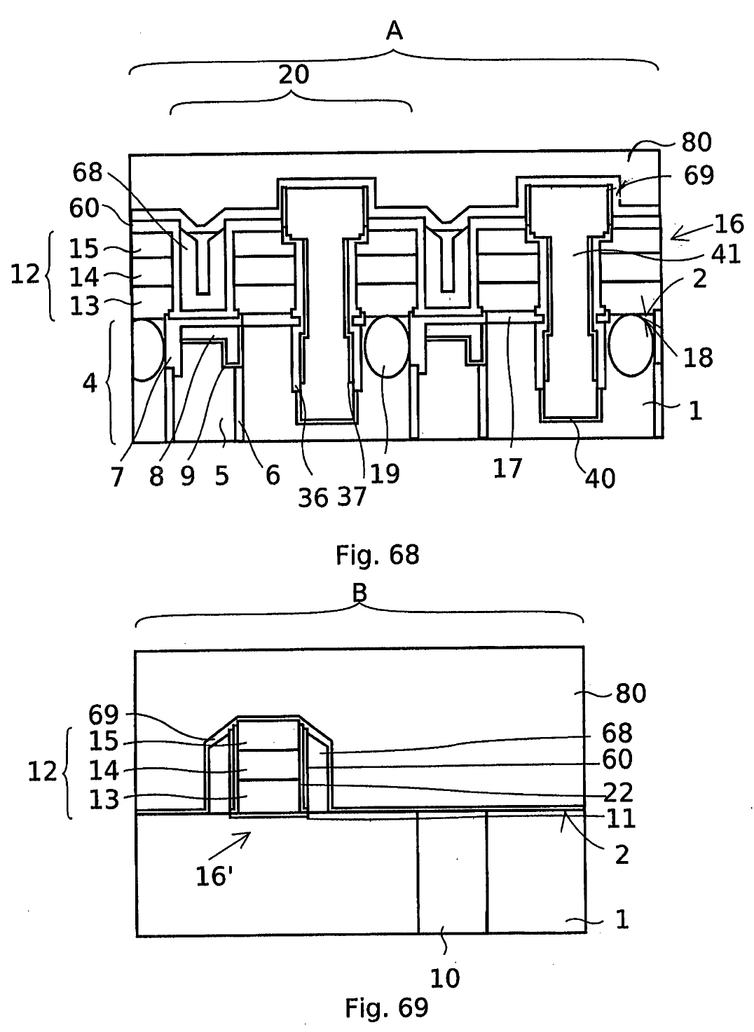

A fourth embodiment is based on the third embodiment. The processing steps illustrated by FIGS. of 43 to 59 and the related description are performed in the fourth embodiment, as well. FIGS. 68 and 69 show cross sections of the semiconductor device processed so far. For the details reference is made to the teaching of the third embodiment.

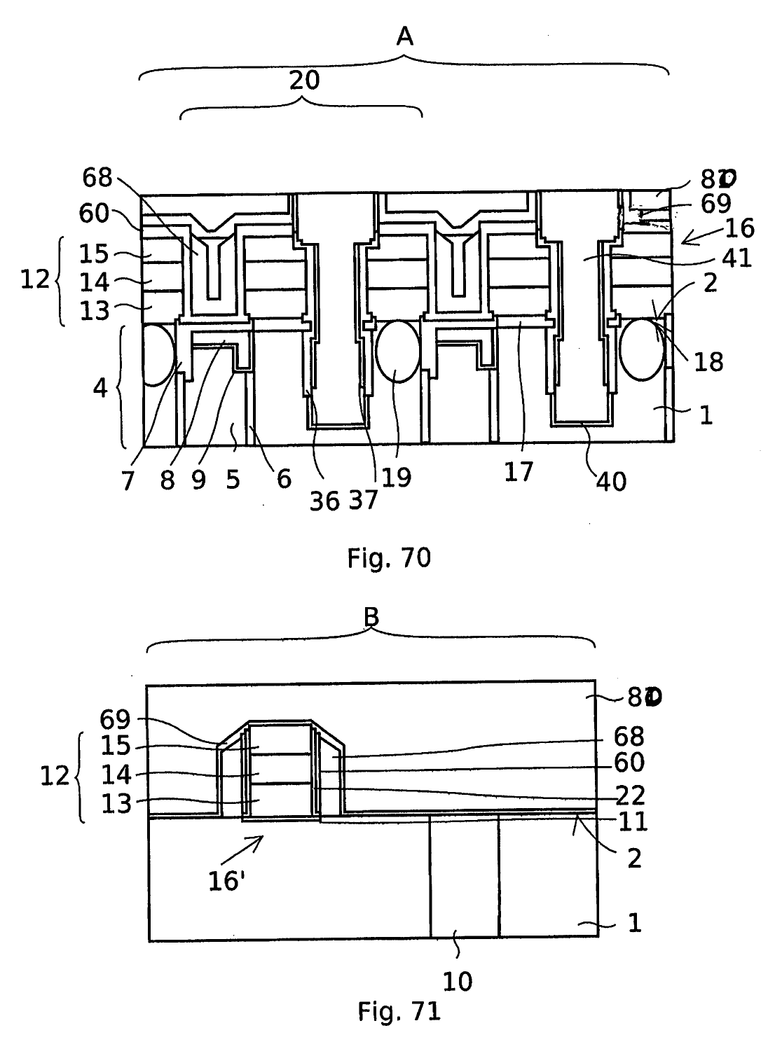

Above the stress layer 69 a spin-on-dielectric 80 is deposited. The spin-on-dielectric layer 80 fully covers the structures formed on the substrate 1. The spin-on-dielectric 80 may be made of spin on glass, silicon glass, BPSG, PSG, silicon oxide, etc. A high-temperature annealing step can be applied to the spin-on-dielectric 80 in order to densify the spin-on-dielectric 80. A polishing step removes parts of the spin-on-dielectric layer 80 provided above the polycrystalline silicon plug 41. Additionally, the polishing step removes the stress layer 69 above the polycrystalline silicon plug 41 (FIGS. 70 and 71).

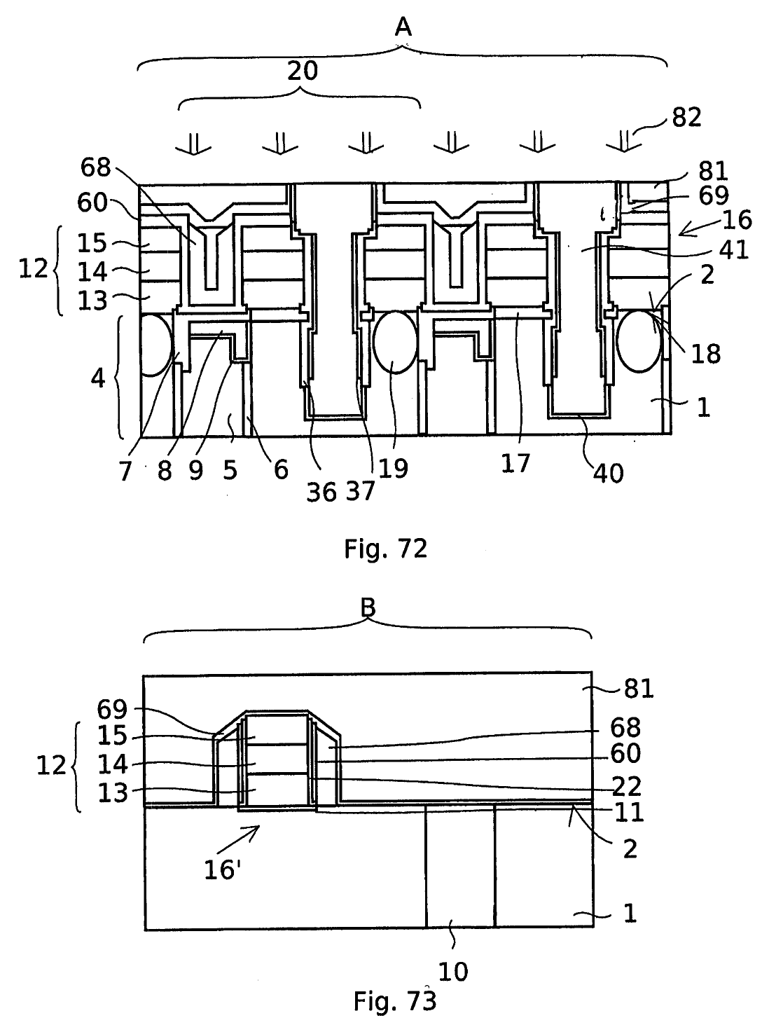

A solution of an anti reflective coating material 82 is applied to the surface of the spin-on-dielectric layer 80. The anti reflective coating 82 fills the scratches in the surface caused by the polishing step. A non-selective etching process is applied to the coated spin-on-dielectric 82. The non-selective etching process provides a uniform etching rate at least with regard to the anti reflective coating material 82 and the spin-on-dielectric 80 (FIGS. 72 and 73).

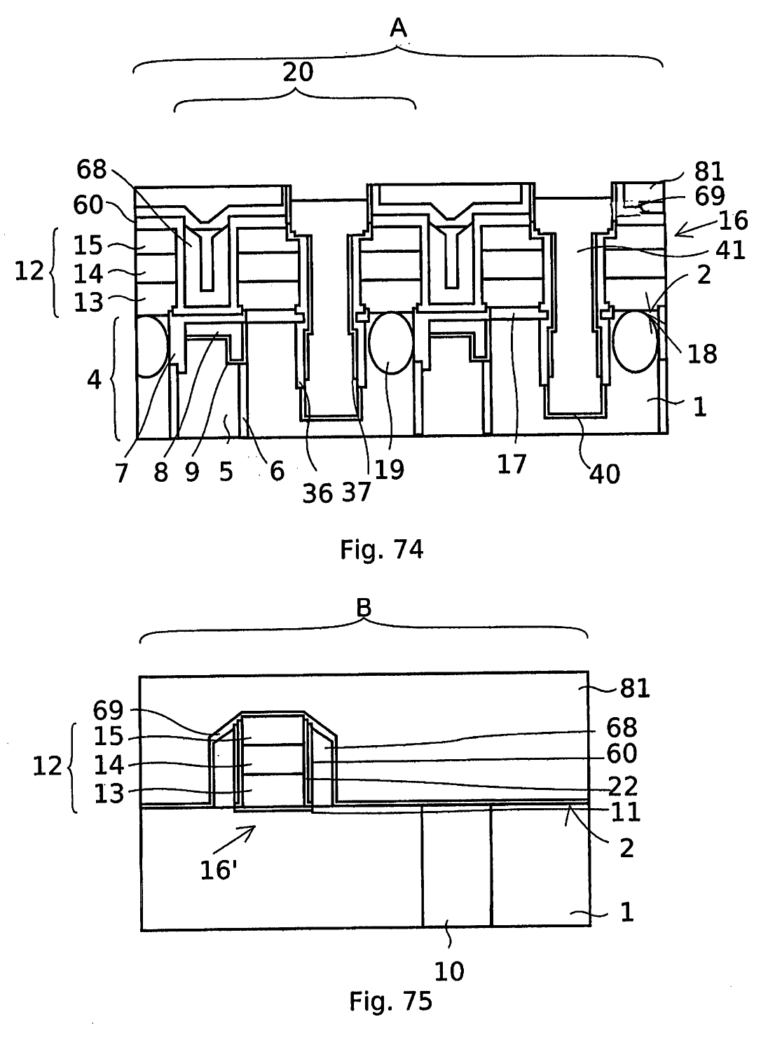

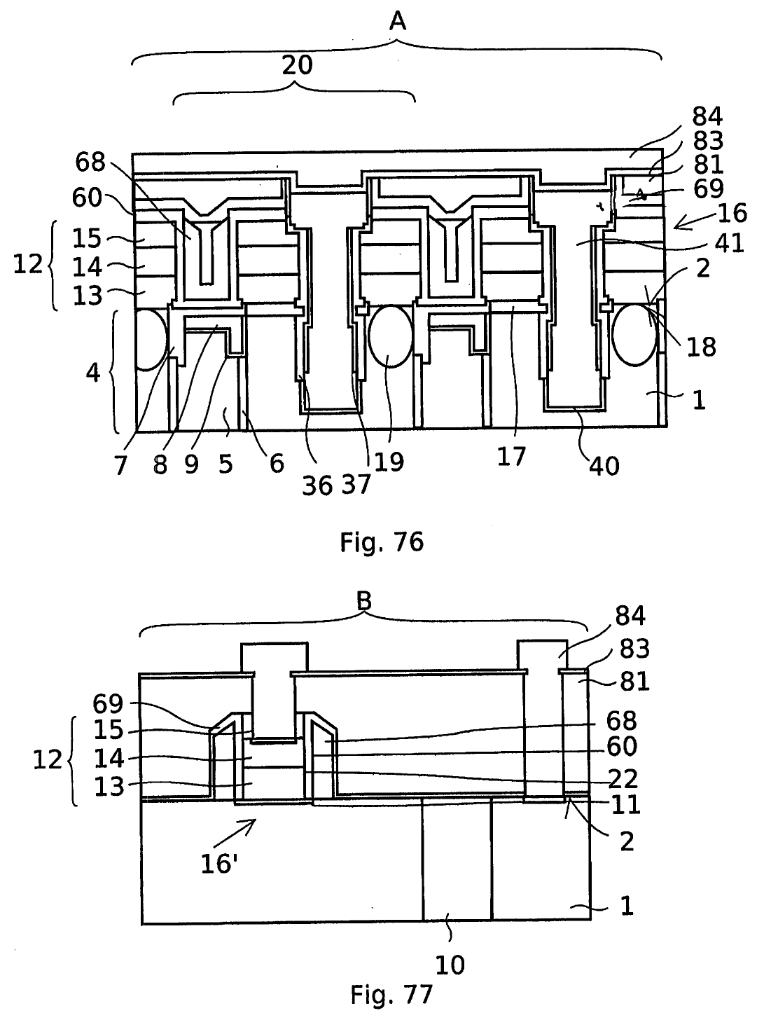

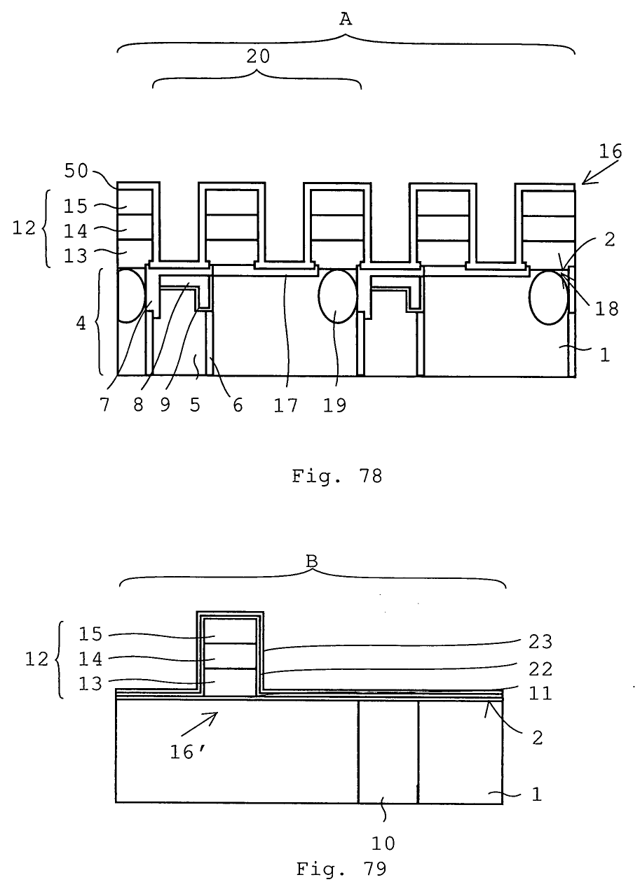

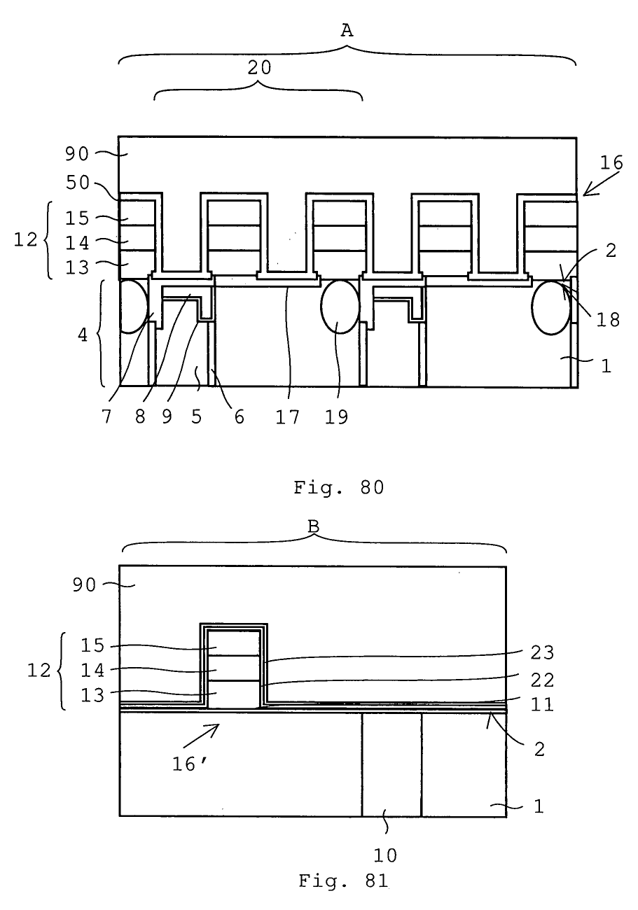

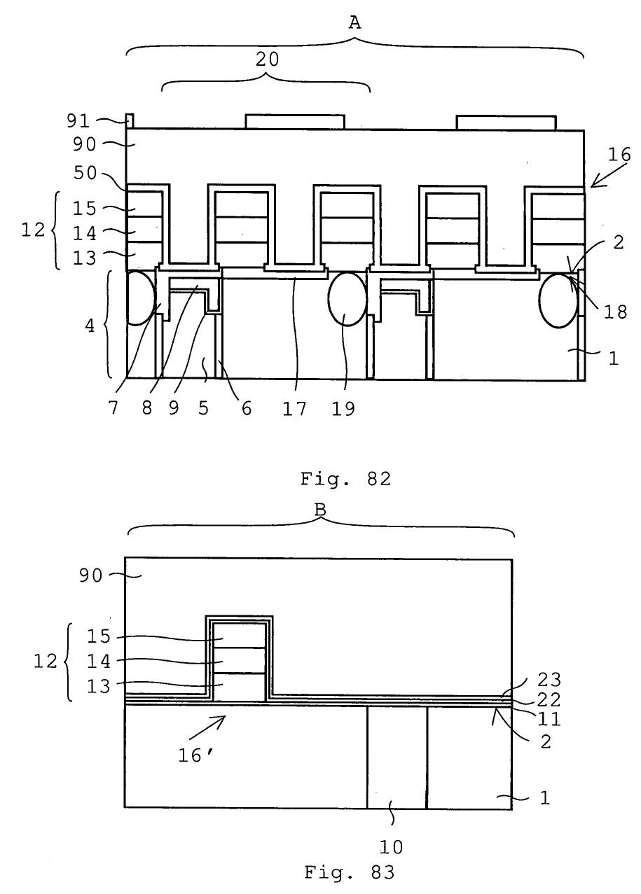

The polycrystalline silicon plug 41 can be recessed by a selective etching process (FIGS. 74 and 75). Contact openings in the substrate area B, barrier layers 83 and word-lines 84 are provided (FIGS. 76 and 77), alike in the third embodiment.

### Fifth Embodiment

The fifth embodiment of a method for forming a semiconductor structure will be explained along with FIGS. 78 to 106. Alike to the above embodiments, conductor lines 16 are formed in a memory field area A and gate stacks 16′ in a support area B. It is referred to FIGS. 1 to 7 for the details.

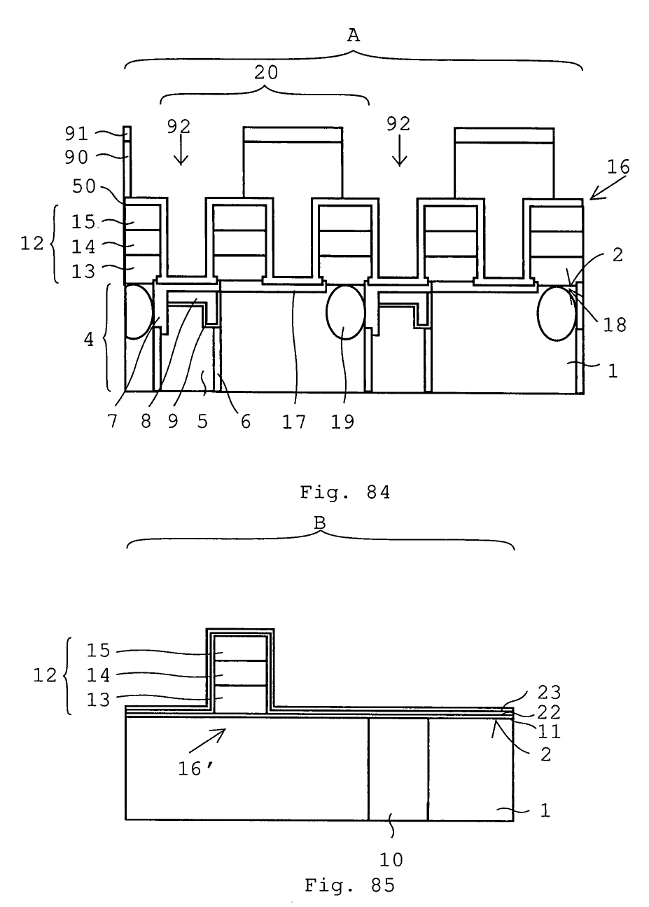

The covering layer 23 is deposited on the conductor lines 16 and the gate stack 16′ (FIGS. 78 and 79). The dimensions of the covering layer 23 may be equal to the dimensions of the covering layer 23 of the first embodiment or of the second embodiment.

A thick layer of a sacrificial material 90, for instance polycrystalline silicon, is deposited in the memory field area A and a support area B (FIGS. 80 and 81). The thickness of the layer 90 may exceed 100 nm.

There is to be formed a trench into the substrate 1 for each memory cell 20 by the subsequent processing steps. At first, a complementary mask 91 is formed on the sacrificial layer 90. The complementary mask 91 covers the area above each memory cell 20, in which the trench will be etched. The covering part of the complementary mask 91 is provided centred above the spacing between two neighbouring conductor lines 16. The complementary mask 91 may be a hard mask made of silicon nitride. The thickness of the complementary mask 91 may be in the range of 10 nm to 50 nm, for instance 20 nm to 40 nm, about 30 nm.

The sacrificial layer 90 is structured by means of an etching process and the complementary mask 91. In the embodiment shown the sacrificial layer 90 only remains in the areas covered by the complementary mask 91 (FIGS. 84 and 85).

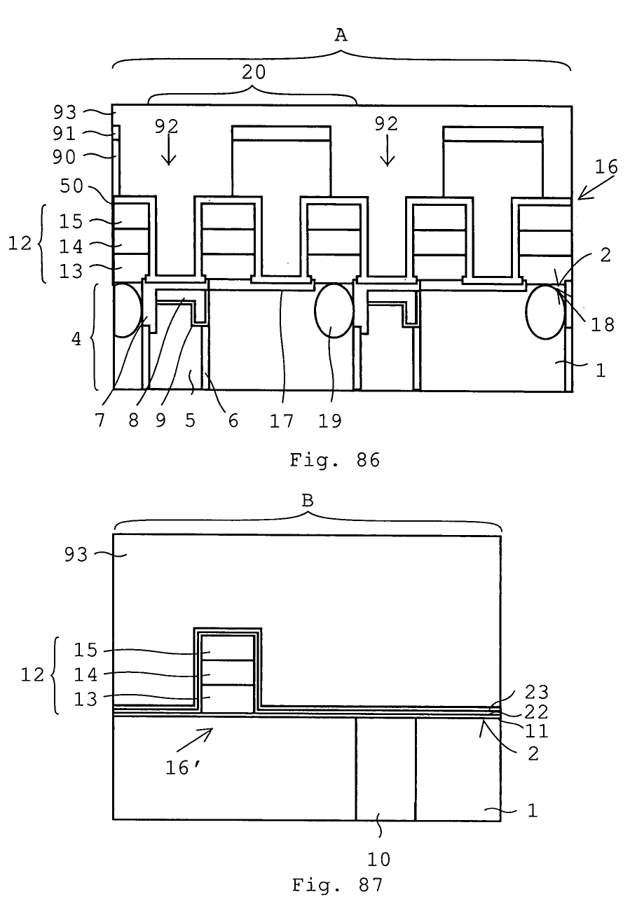

A spin-on-dielectric layer 93 is provided over the whole substrate 1, hence covering the support area B and a memory field area A. The spin-on-dielectric layer 93 may comprise silicon glass. The thickness of the spin-on-dielectric layer 93 may exceed 100 nm (FIGS. 86 and 87).

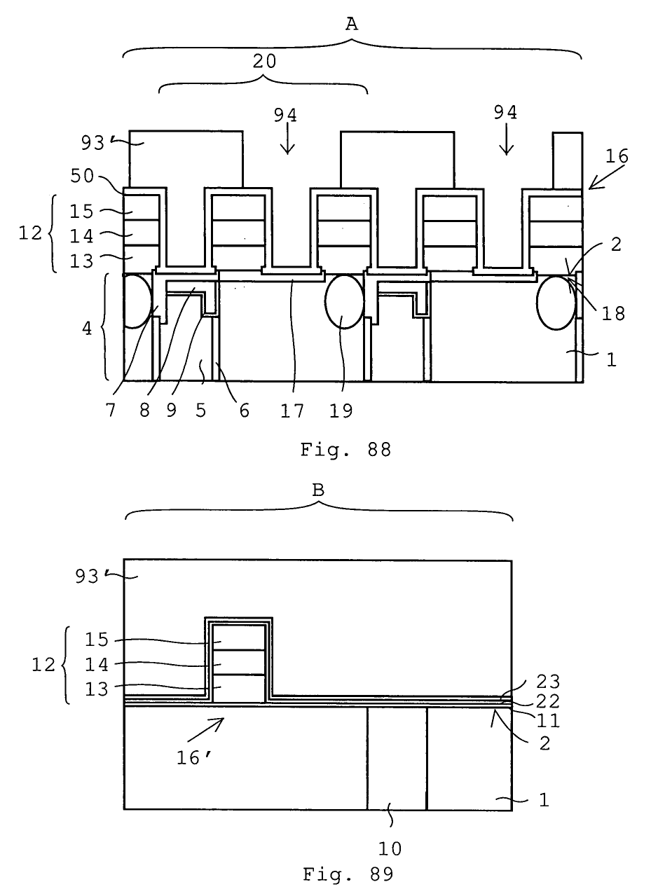

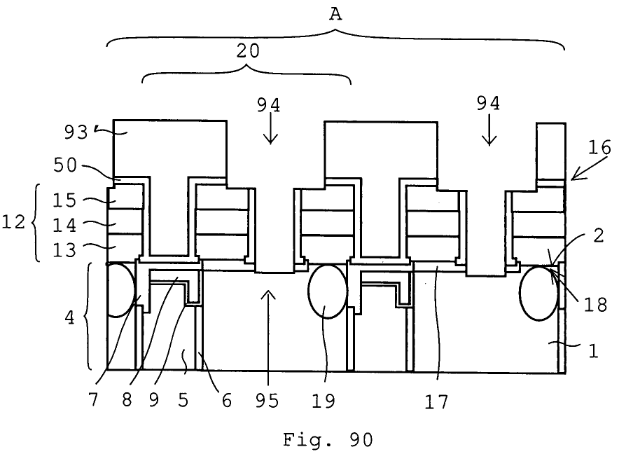

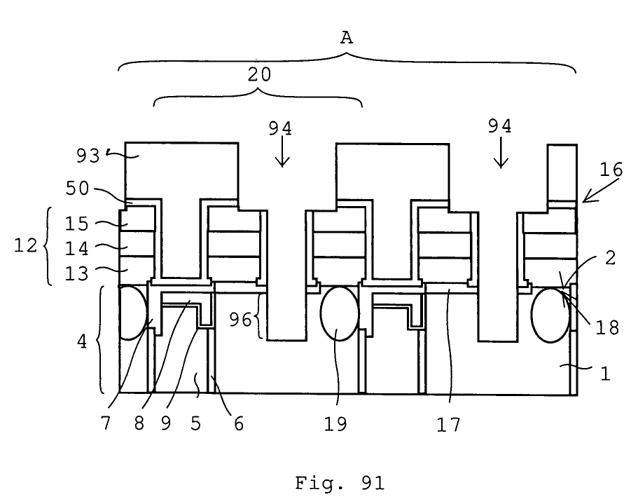

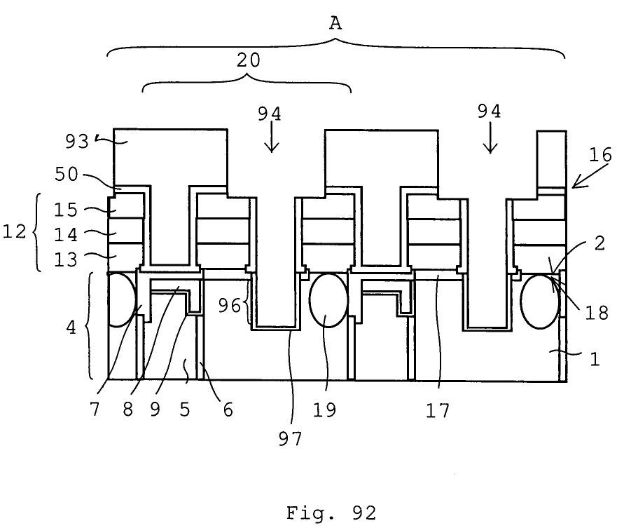

A chemical mechanical polishing step may be applied until the complementary hard mask 91 or the sacrificial layer 90 is exposed. A selective etching process removes the complementary hard mask 91 and the sacrificial layer 90 below (FIGS. 88 and 89). Thus, the inverse pattern of the complementary mask 91 is transferred into a new mask 93′ comprising the spin-on-dielectric 93. The selective etching process etches selectively polycrystalline silicon with a higher etching rate compared to its etching rate of the covering layer 23. The covering layer 23 may be formed of silicon nitride. Thus, trenches 94 are formed between two neighbouring conductor lines 16. The width of the trenches 94 is predefined by the distance of the two neighbouring conductor lines 16.

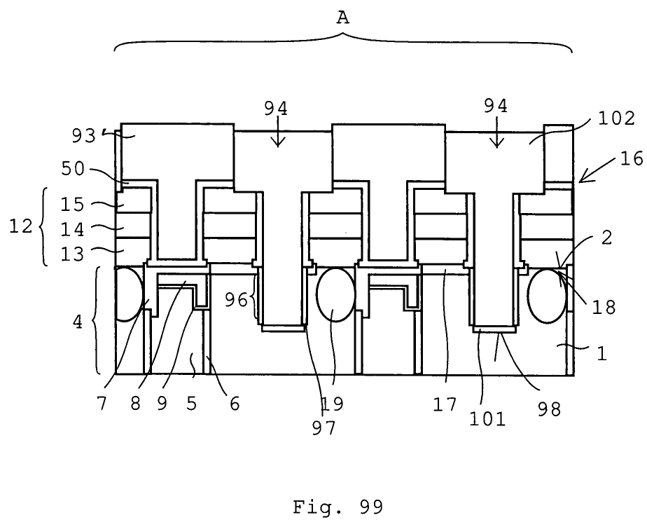

The next processing steps just apply to the memory field area A as the support area B remains protected by the mask 93′ comprising the spin-on-dielectric. Therefore, illustrations of the support area B are omitted until FIG. 100.

The exposed isolation layer 17 is etched away to lay free the substrate 1 (FIG. 90). The etching through can be performed by the selective etching process or by a different etching process having a higher etching rate with respect to the material of the isolation layer 17.

A selective etching process which etches the substrate 1 selectively with respect to the covering layer 23 is used to form a trench 96 in the substrate 1 (FIG. 91). It will be referred to the trench 96 as collar trench 96. The width of the collar trench 96, i.e. its lateral dimension orthogonal to the orientation of the conductor lines 16, can be enlarged by an isotropic etching process.

A spacer oxide 97 is grown on the surface of the collar trench 96 (FIG. 92). Appropriate techniques to grow such a spacer oxide are given as examples in the above embodiments, for instance LPRO.

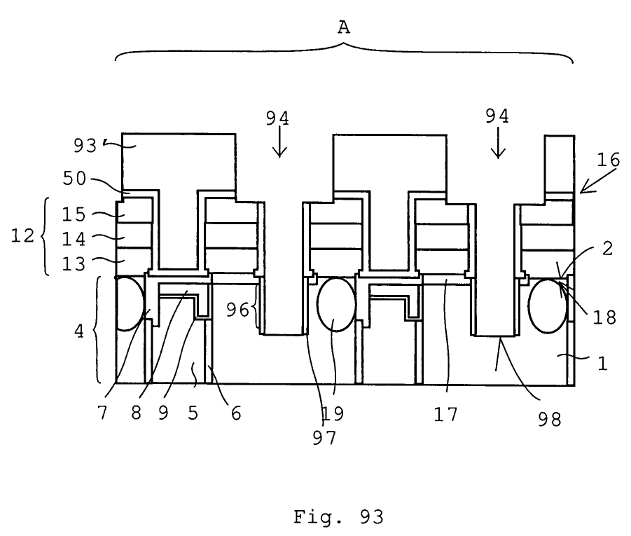

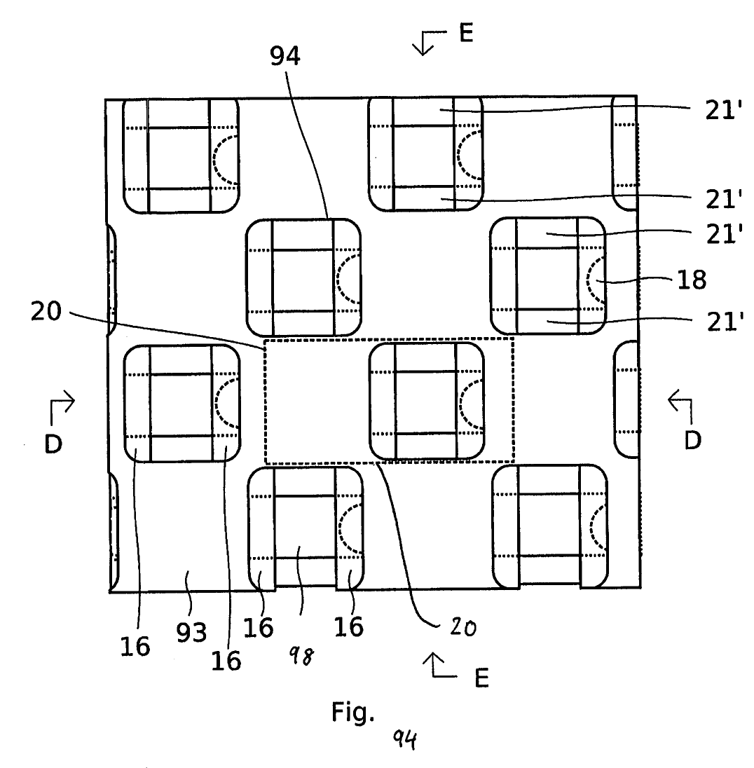

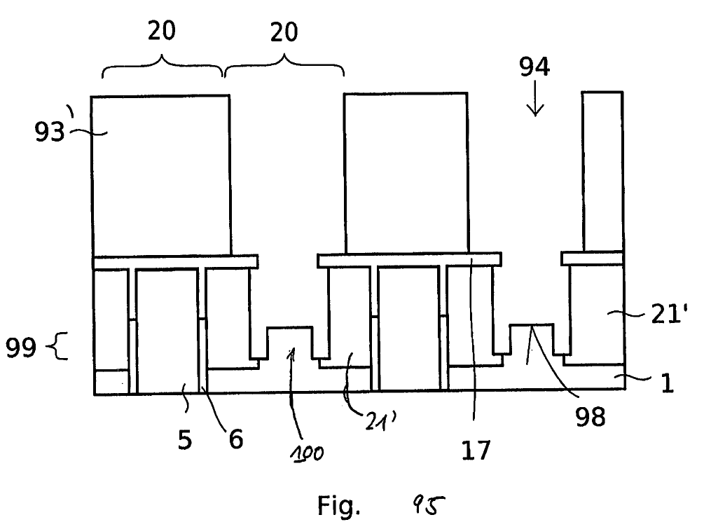

The spacer oxide 97 is selectively removed from the bottom part 98 of the collar trench 96 by a selective anisotropic etching technique (FIG. 93). The side walls of the collar trench 96 remain covered by the spacer oxide 97.

FIG. 94 shows the memory field area A in a top view. A cross-section of FIG. 93 corresponds to the layer D-D. A cross-section corresponding to the layer E-E is shown in FIG. 95.

The masking spin-on-dielectric layer 93′ covers most of the memory field area A. The above etching process structures the substrate 1 through the trenches 94. As outlined above, the conductor lines 16 further restrict the areas affected by the selective etching processes. At present stage, the bottom part 98 of the collar trench 96 is exposed to the selective etching processes.

Isolation trenches 21′ are separating rows of neighbouring memory cells 20. The isolation trenches 21′ are arranged orthogonal to the conductor lines 16. The trenches 94 are having a cross-section such that the isolation trenches 21′ are partially exposed. The isolation trenches 21′ are filled with dielectric material which may comprise silicon oxide or silica glass, hence materials which are etched by the anisotropic selective etching process. Therefore, the side walls of the isolation trenches 21′ will be etched along with the spacer oxide 97 on the bottom part of the collar trench 96. The etching of the spacer oxide 97 is self terminated as the substrate 1 below the spacer oxide 97 is passive with respect to the anisotropic selective etching process. The anisotropic selective etching process, however, continues to etch the isolation trenches 21′ below the level of the bottom part of the collar trench 96. This leads to the freestanding substrate fin 100, as seen in FIG. 95.

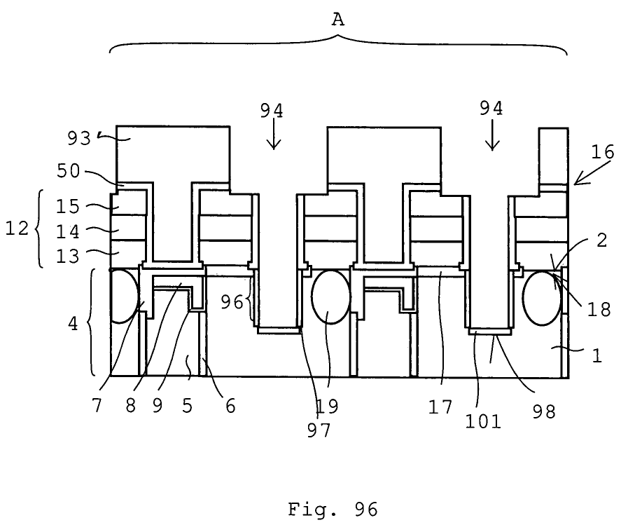

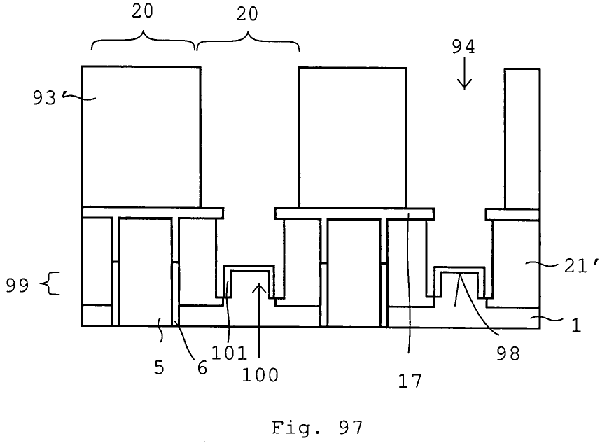

A gate oxide 101 is grown on the freestanding substrate fin 100 (FIGS. 96 and 97). Appropriate techniques to grow such a gate oxide are given as examples in the above embodiments.

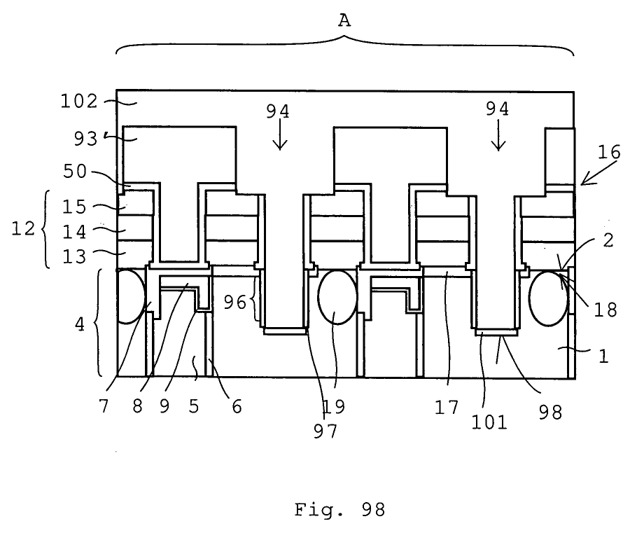

The trenches 94, 96 are filled with a conductive polycrystalline silicon plug 102 (FIG. 98). The polycrystalline silicon plug 102 may be polished and subsequently recessed by a selective etching process (FIG. 99). The mask 93′ is stripped off, for instance by a wet etching technique based on hydrofluoric acid (FIGS. 100 and 101). Implants for the support devices may be implanted in the support area B. Additional spacers can be deposited and structured along the side walls of the gate stag 16′.

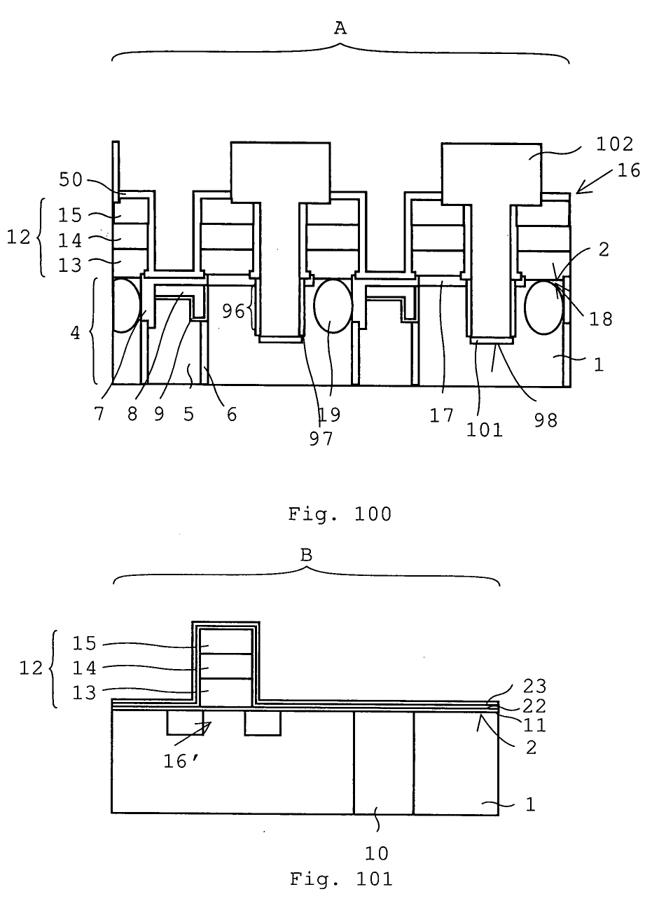

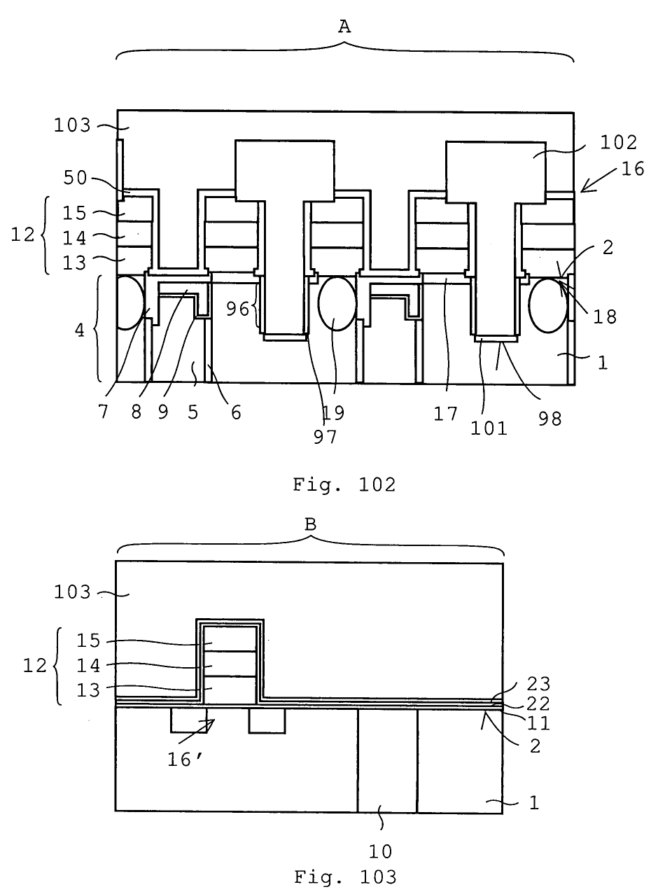

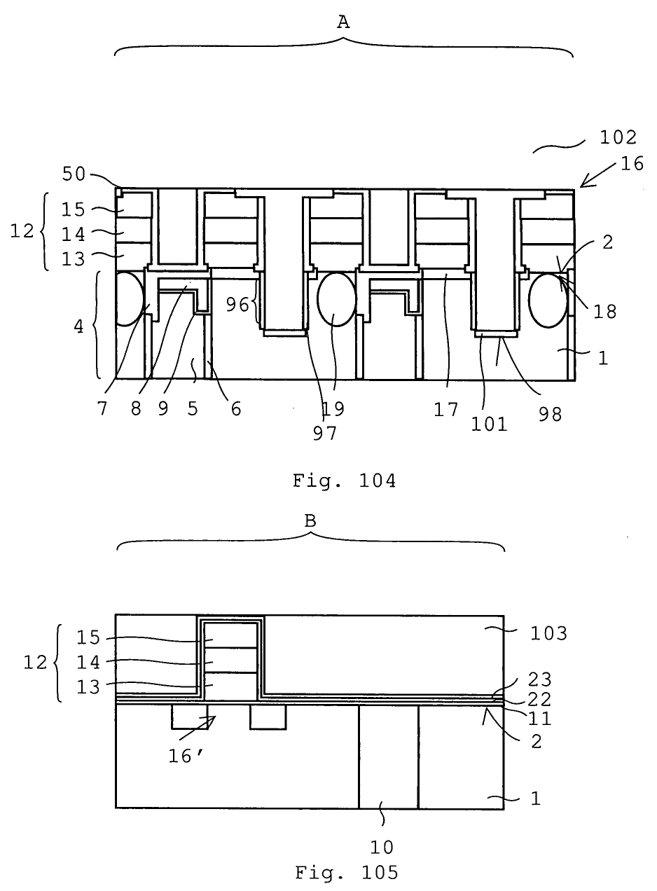

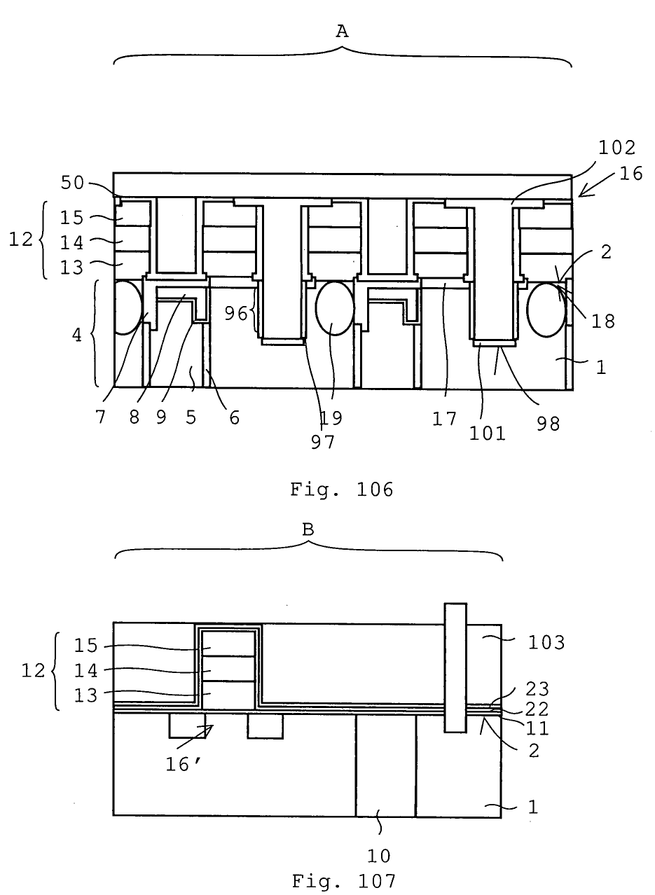

A further spin-on-dielectric layer 103 is applied, for instance to planarize the semiconductor device (FIGS. 102 and 103). A chemical mechanical polishing step is applied which may optionally use the cap nitride 15 as stop layer (FIGS. 104 and 105). Finally, word-lines 84 and a contact 84 to the substrate 1 are formed (FIGS. 106 and 107).

### Sixth Embodiment

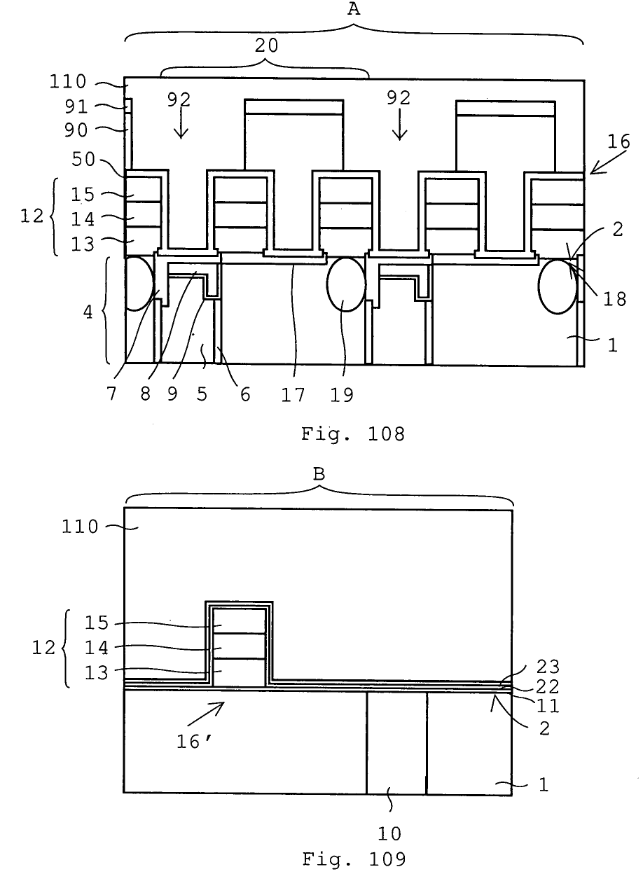

A sixth embodiment is based on the embodiment. The processing steps illustrated along with FIGS. 78 to 85 and described in the related passages are performed to provide a structure illustrated in FIGS. 108 and 109, except feature 110. A spin-on-dielectric 110 is deposited on the above structure.

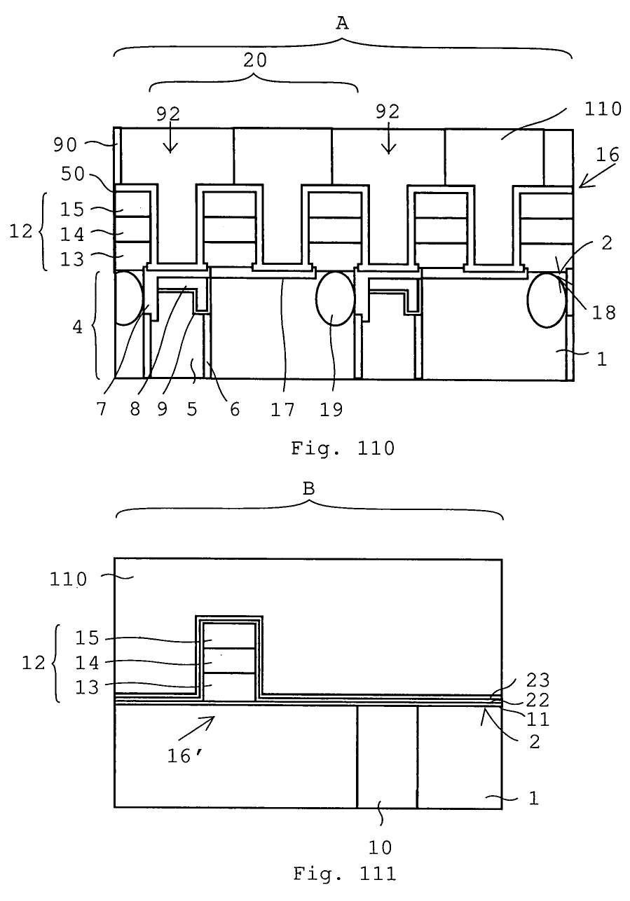

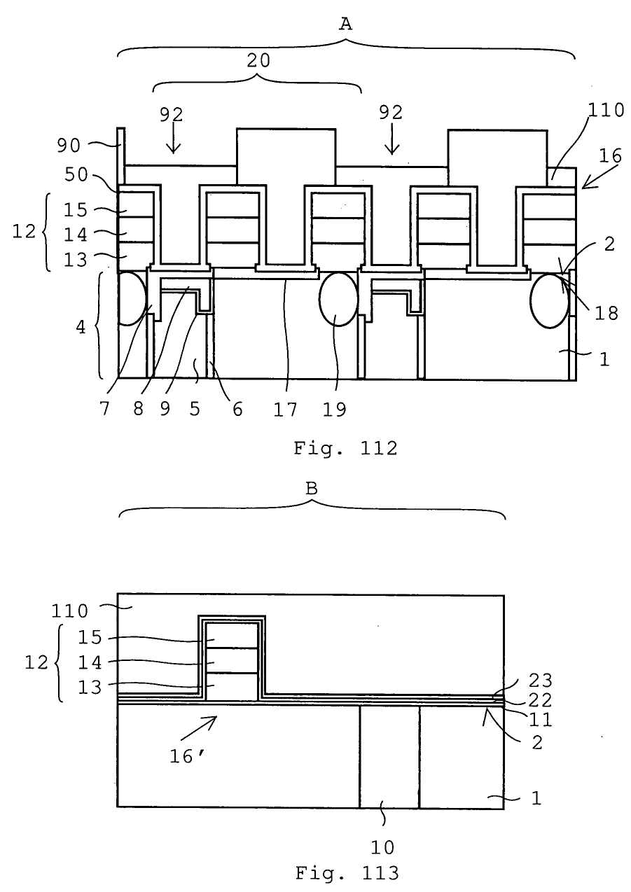

The spin-on-dielectric 110 is polished by a chemical mechanical polishing step (FIGS. 110 and 111) at least until the polycrystalline silicon plugs 90 are exposed. Subsequently, the spin-on-dielectric 110 is selectively recessed with respect to the polycrystalline silicon plugs 90 (FIGS. 112 and 113).

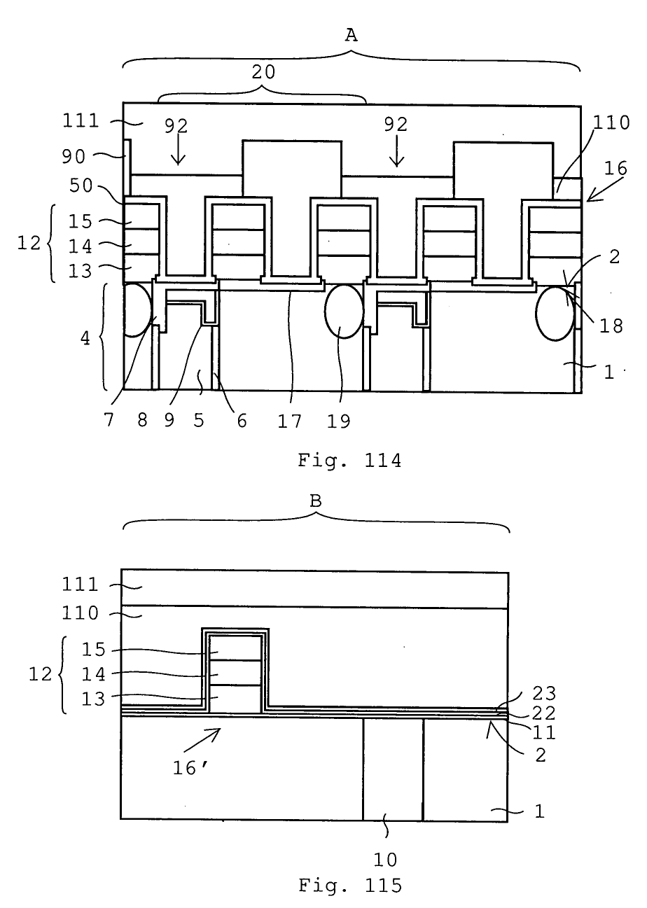

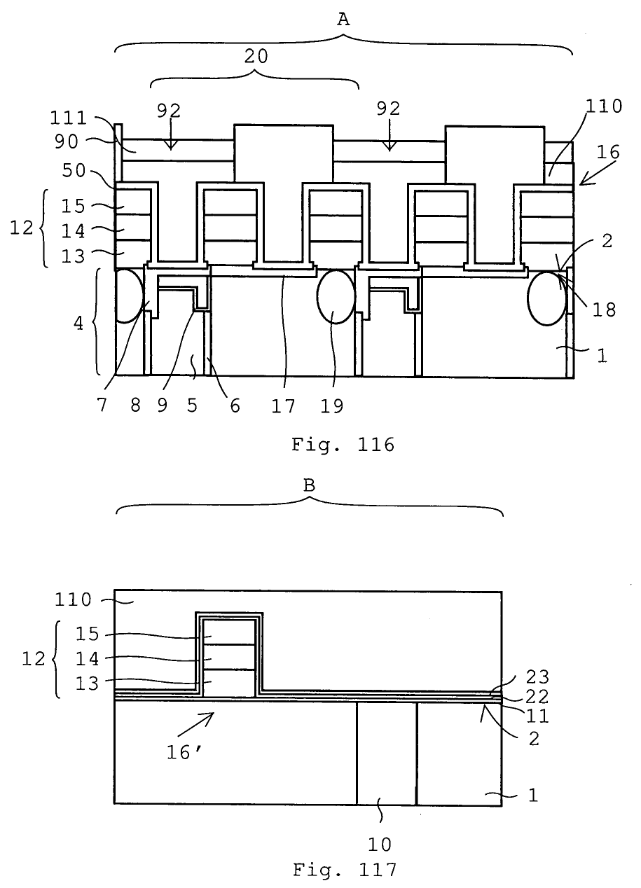

A masking layer 111 comprising or made of silicon nitride is deposited (FIGS. 114 and 115). The masking layer 111 fills the spacing between the polycrystalline silicon plugs 92. The vertical dimensions of the masking layer 111 are, therefore, larger in the memory field area A compared to the support area B. An anisotropic etching process reduces the thickness of the masking layer 111 until the masking layer 111 is removed in the support area B. The masking layer 111 remains between the polycrystalline silicon plugs 90 (FIGS. 116 and 117).

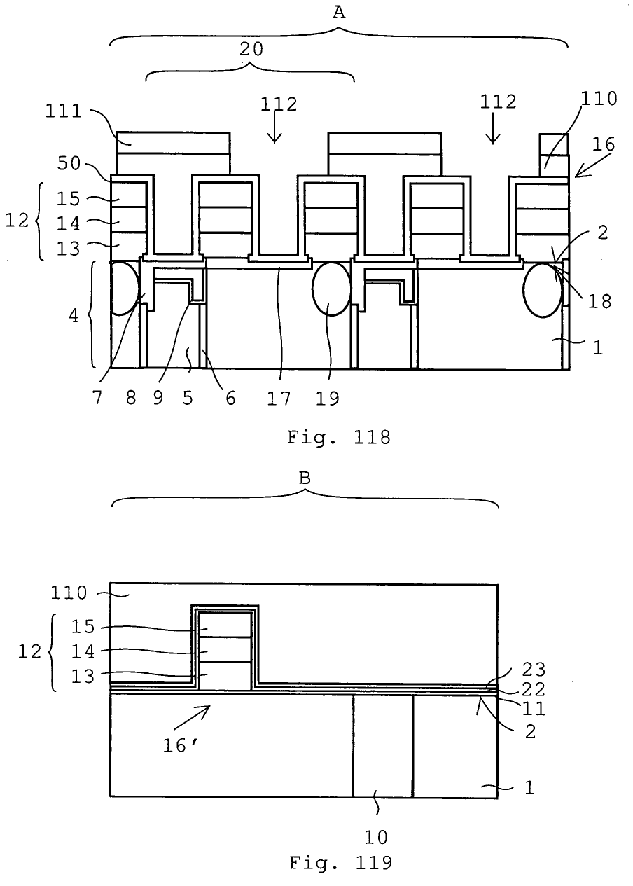

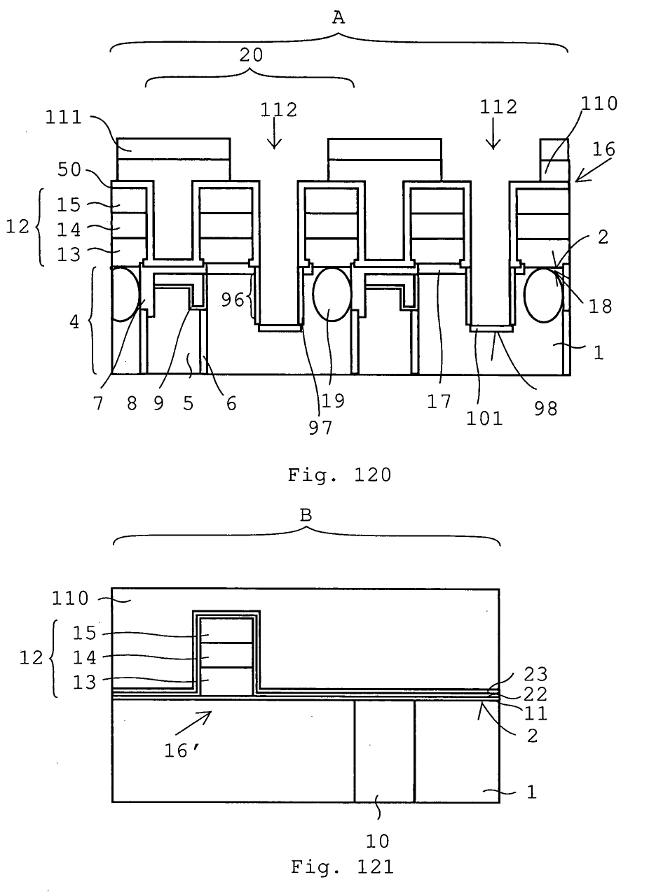

The polycrystalline silicon plugs 90 are selectively removed, hence providing trenches 112 in each memory cell 20 above the substrate 1 (FIGS. 118 and 119). Additionally, the masking layer 111 protects underlying structures against the subsequent etching processes. The masking layer 111 and the covering layer 23 are defining the areas which are etched by the selective etching processes. A collar trench 96 is formed in the substrate 1 according to the fifth embodiment or any of the other embodiments (FIGS. 120 and 121). An oxide spacer 97 and a gate oxide 101 are grown and deposited on the surfaces of the collar trench 96. The bottom area 98 may have a fin type structure.

In subsequent processing-steps the trenches 112 are filled with a conductive material, for instance highly doped polycrystalline silicon, the masking layer 111 may be stripped and contact openings and word-lines are formed. The respective details are given in the above embodiments.

The semiconductor device, in particular memory semiconductor device, which may be formed according to one of the above embodiments, is provided with the following features. In a memory field area A a plurality of memory cells 20 are arranged. Each of these memory cells 20 comprises a trench capacitor 5, 6 and a selection transistor 40, 41, 13 both arranged in the substrate 1. A gate electrode 41 and a gate dielectric 40 of the selection transistor are arranged in a trench 39 formed into the substrate 1.

A plurality of conductor lines 16 are arranged on the substrate 1, i.e. above the trench capacitors and the selection transistors. The conductor lines 16 are made of a staple of a lower conductive part and an upper cap layer. Two conductor lines 16 are crossing each memory cell 20. The substrate 1 is in electrical contact with exactly one of the two conductor lines 16 in each memory cell 20.

The conductor lines 16 are displaced with respect to the trench 39 and the gate electrode 41. The trench 39 and the gate electrode 41 of the memory cell 20 are arranged centered with respect to a layer in the middle between the two conductor lines 16 which are crossing the memory cell 20. That is to say, the trench 39 and the gate electrode 41 are arranged in or below the gap between the two conductor lines 16. The capacitor structure can be arranged displaced to the conductor lines 16, too.

Isolation trenches 21′ are arranged in the substrate 1 and are running orthogonal to the conductor lines 16. Thus, the memory cells 20 are arranged in rows separated by the isolation trenches 21′. The memory cells 20 of one row are isolated from each other by their respective capacitor structures.

Gate stacks 16′ are arranged in the support area B. The structure of the gate stacks 16′ consists of a lower conductive part and an upper cap layer which is identical to the ones of the conductor lines 16.

Word-lines are arranged above the conductor lines. The word-lines are electrically connected to the gate electrodes by vertical plugs arranged between the conductor lines 16.

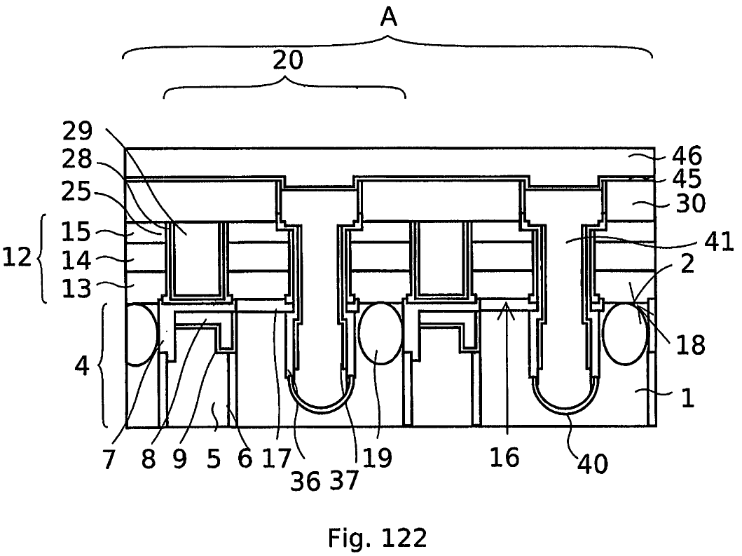

A further embodiment is shown in FIG. 122. The bottom part of the trench is formed in a convex or arched shape.

Although the present invention has been explained on the basis of six embodiments; the present invention is not limited there on. In particular, materials, dimensions, etching processes, deposition techniques taught in one embodiment can be used for another embodiment if not stated explicitly otherwise. Thus, it is intended that the present invention is only limited by the scope of the claims attached herewith.

The active device formed the substrate is just an example for other active devices. In particular the present invention is not limited to the shape of the gate dielectric, the gate electrode. i.e. the polycrystalline silicon plug. The gate dielectric may be folded, flat, rounded etc. The transistor may be a EUD device, too. The bottom area of the trench may be curved, e.g. convexly shaped, being deeper in the middle than at the corners.

The above embodiments are using a gate oxide as example for a gate dielectric. Instead of silicon oxide, silicon nitride, high-k dielectrics, hafnium oxide, zirconium oxide, etc can be used.

What is claimed is:

1. A method for forming an active device of a semiconductor device, comprising the steps of:
(a) providing a substrate comprising a substrate surface;
(b) forming conductor lines above the substrate surface and orientated along a first direction;
(c) forming a mask above the conductor lines;
(d) etching at least one trench into the substrate using the conductor lines as a masking structure and by using the mask to define the lateral dimension of the at least one trench along the first direction; and
(e) forming an active device in the at least one trench.

2. The method according to claim 1, wherein the mask is formed with mask openings defining the lateral dimensions of the at least one trench along the first direction.

3. The method according to claim 1, wherein a thin covering layer is formed at least partly on side-walls of the conductor lines preceding the etching of the at least one trench into the substrate.

4. The method according to claim 3, wherein the at least one trench is etched into the substrate by a selective etching process with respect to the mask and the thin covering layer.

5. The method according to claim 1, wherein a dielectric material is deposited filling up spacings between the conductor lines prior forming the mask; and wherein openings of the mask are transferred into the dielectric material by an etching process selectively etching the dielectric material.

6. The method according to claim 1, wherein the forming the mask comprises the steps of:
(a) depositing a sacrificial layer filling up spacings between the conductor lines;
(b) removing portions of the sacrificial layer to define a complementary mask being complementary to the mask;
(c) filling the removed portions of the sacrificial layer by a mask material; and
(d) selectively removing the residual sacrificial layer with respect of the mask material for forming the mask.

7. The method according to claim 6, wherein the mask material is polished before step (d) until the sacrificial layer is exposed.

8. The method according to claim 3, wherein the thin covering layer comprises silicon nitride.

9. The method according to claim 3, wherein the thin covering layer is formed with a thickness at most equal to a third of a distance between neighbouring conductor lines.

10. The method according to claim 3, wherein preceding the forming of the mask, spacings between the conductor lines are filled with spin-on-dielectric or polycrystalline silicon; and wherein the at least one trench is formed through the spin-on-dielectric or polycrystalline silicon by means of a highly selective etching process with respect to the mask and the thin covering layer.

11. The method according to claim 7, wherein the spin-on-dielectric is at least one of silicon oxide, silicon oxynitride, spin-on-glass, boron phosphate silica glass and phosphate silica glass.

12. The method according to claim 1, wherein a gate dielectric is formed at least partly on the surface of the at least one trench; and wherein the trench is filled up with a conductive material for forming a gate electrode.

13. The method according to claim 12, wherein the bottom part of the at least one trench is structured into a fin form or the bottom part is structured to a u-shaped device preceding the depositing of the gate dielectric for a forming a fin gate selection transistor.

14. A method for forming an integrated circuit having an active semiconductor device, comprising the steps of:
(a) providing a substrate comprising a substrate surface divided in support areas and memory field areas;
(b) forming conductor lines by depositing a stack of a lower conductive layer and a protective cap layer in the support areas and memory field areas on the substrate surface and by structuring the stack to the conductor lines orientated along a first direction in the memory field area and to gate stack in the support area;
(c) forming a mask above the conductor lines;
(d) etching at least one trench into the substrate using the conductor lines as a masking structure and by using the mask to define the lateral dimension of the at least one trench along the first direction; and
(e) forming an active device in the at least one trench.

15. The method according to claim 14, wherein the mask for the etching of the at least one trench is formed above the conductor lines for defining the at least one trench, the mask having mask openings being essentially wider than the distance between the conductor lines.

16. The method according to claim 14, wherein a thin covering layer is deposited on the support areas and memory areas and structured by an anisotropic etching process removing the planar parts of the covering layer, preceding the forming of the mask.

17. The method according to claim 14, wherein a spin-on-dielectric layer is deposited filling up the spacings between the conductor lines; and wherein the spin-on-dielectric layer is transformed into the mask by a lithographic structuring process.

18. The method according to claim 17, wherein the at least one trench is etched into the substrate by a highly selective etching process with respect to the mask and the thin covering layer.

19. The method according to claim 15, wherein a stress layer is deposited on the covering layer in the support areas and a second covering layer is deposited in the support areas and the memory areas, preceding the forming of the mask.

20. The method according to claim 17, wherein the at least one trench is filled with a conductive material for forming a gate electrode of the active device in the at least one trench; the mask is stripped of; and active devices are structured in the support area.

21. The method according to claim 20, wherein a silicon oxide-based layer is deposited after forming the gate electrode; wherein the conductive material of the gate electrodes is recessed below the top surface of the silicon oxide-based layer; and word-lines are structured on the silicon oxide-based layer and the recessed gate electrodes.

22. The method according to claim 21, wherein the silicon oxide-based layer is polished to expose the gate electrode; wherein an antireflective coating material is deposited on the polished silicon oxide-based layer and the silicon oxide-based layer; and wherein the antireflective coating material are etched by a non-selective etching process before the gate electrode is recessed.

23. The method according to claim 22, wherein the non-selective etching process provides a uniform etching rate for the silicon oxide-based layer and the anti-reflective coating material.

24. A method for forming an integrated circuit having an active semiconductor device, comprising the steps of:
(a) providing a substrate having a substrate surface;
(b) forming conductor lines on top of the substrate surface; and
(c) forming gate electrodes between the structured conductor lines extending down into the substrate.

25. The method according to claim 24, wherein a staple comprising a conductive layer and a cap layer is structured to the conductor lines and side walls of the conductor lines are covered by a spacer layer made of the same material as the cap layer.

26. The method according to claim 24, wherein the gate electrodes are formed by selectively etching trenches between the conductor lines into the below substrate, depositing a gate dielectric in the trenches and filling the trenches with a conductive material.

27. An integrated circuit comprising a plurality of conductor lines arranged on a substrate and a plurality of memory cells are arranged in the substrate, each memory cell is covered by two of the conductor lines and comprises an active device arranged laterally between and vertically below the two of the conductor lines.

28. The integrated circuit according to claim 27, wherein the active device is a field effect transistor.

29. The integrated circuit according to claim 27, wherein the active device is a fin type transistor or an extended u-shaped transistor.

30. The integrated circuit according to claim 29, wherein the fin type transistor comprises an electrode having a concave shaped bottom surface.

31. The integrated circuit according to claim 27, wherein at least one gate stack is provided in the support area and the gate stacks and the conductor lines are formed of the equal lower conductive layer and upper cap layer.
